(19) United States
(12) Patent Application Publication
(10) Pub. No.: US 2024/0421112 A1
(43) Pub. Date: Dec. 19, 2024

(54) SEMICONDUCTOR ELEMENT AND SEMICONDUCTOR DEVICE

(71) Applicant: ROHM CO., LTD., Kyoto (JP)

(72) Inventor: Yuta KASHITANI, Kyoto (JP)

(73) Assignee: ROHM CO., LTD., Kyoto (JP)

(21) Appl. No.: 18/738,727

(22) Filed: Jun. 10, 2024

(30) Foreign Application Priority Data
Jun. 13, 2023 (JP) 2023-097092

(51) Int. Cl. H01L 23/00; H01L 23/31

(52) U.S. Cl. CPC H01L 24/17; H01L 23/3107; H01L 24/13; H01L 24/16; H01L 2224/13083; H01L 2224/1357; H01L 2224/16054; H01L 2224/16055; H01L 2224/16245; H01L 2224/1703; H01L 2224/17051; H01L 2924/381

(57) ABSTRACT

A semiconductor element includes: an element front surface and an element back surface facing an opposite side from the element front surface; first and second electrodes that are formed over the element front surface; first electrode terminals in contact with the first electrode; second electrode terminals in contact with the second electrode; a first region in which the first electrode terminals are arranged; and a second region in which the second electrode terminals are arranged, wherein the number of the second electrode terminals per unit area in the second region is smaller than the number of the first electrode terminals per unit area in the first region, and wherein an area of each of the second electrode terminals is larger than an area of each of the first electrode terminals when viewed from a thickness direction which is perpendicular to the element front surface.

### CROSS-REFERENCE TO RELATED APPLICATION

This application is based upon and claims the benefit of priority from Japanese Patent Application No. 2023-097092, filed on Jun. 13, 2023, the entire contents of which are incorporated herein by reference.

### TECHNICAL FIELD

The present disclosure relates to a semiconductor element and a semiconductor device.

### BACKGROUND

In the related art, a semiconductor device that includes a semiconductor element and a wiring part bonded to each other by flip-chip bonding, and a sealing resin that seals the semiconductor element and the wiring part, is disclosed.

### BRIEF DESCRIPTION OF DRAWINGS

The accompanying drawings, which are incorporated in and constitute a part of the specification, illustrate embodiments of the present disclosure.

FIG. 1 is a schematic perspective view of a semiconductor device according to a first embodiment of the present disclosure.

FIG. 2 is a schematic plan view showing an internal structure of the semiconductor device of FIG. 1.

FIG. 3 is a schematic plan view of the semiconductor device of FIG. 2 with a portion of a semiconductor element omitted from the semiconductor device.

FIG. 4 is a schematic back view of the semiconductor device of FIG. 1.

FIG. 5 is a schematic plan view of a semiconductor element.

FIG. 6 is a schematic cross-sectional view of the semiconductor element taken along line F6-F6 in FIG. 5.

FIG. 7 is a schematic cross-sectional view of the semiconductor device taken along line F7-F7 in FIG. 2.

FIG. 8 is an enlarged schematic cross-sectional view of a first electrode terminal and its surroundings in FIG. 7.

FIG. 9 is an enlarged schematic cross-sectional view of a second electrode terminal and its surroundings in FIG. 7.

FIG. 10 is a schematic plan view of a semiconductor element of a comparative example.

FIG. 11 is a schematic cross-sectional view of the semiconductor element taken along line F11-F11 in FIG. 10.

FIG. 12 is a schematic cross-sectional view of a semiconductor device of the comparative example, including the semiconductor element of FIG. 11.

FIG. 13 is a schematic plan view of a semiconductor element of a semiconductor device according to a second embodiment of the present disclosure.

FIG. 14 is a schematic cross-sectional view of the semiconductor element taken along line F14-F14 in FIG. 13.

FIG. 15 is a schematic cross-sectional view of a semiconductor device.

FIG. 16 is an enlarged schematic cross-sectional view of a dummy terminal and its surroundings in FIG. 15.

FIG. 17 is a schematic plan view of a semiconductor element of a semiconductor device according to a third embodiment of the present disclosure.

FIG. 18 is a schematic cross-sectional view of the semiconductor element taken along line F18-F18 in FIG. 17.

FIG. 19 is a schematic plan view of a semiconductor element of a semiconductor device according to a modification.

FIG. 20 is a schematic plan view of a semiconductor element of a semiconductor device according to a modification.

FIG. 21 is a schematic plan view of a semiconductor element of a semiconductor device according to a modification.

FIG. 22 is a schematic plan view of a semiconductor element of a semiconductor device according to a modification.

FIG. 23 is a schematic plan view of a semiconductor element of a semiconductor device according to a modification.

FIG. 24 is a schematic plan view of a semiconductor device according to a modification with a portion of a semiconductor element omitted from the semiconductor device.

FIG. 25 is a schematic cross-sectional view of a semiconductor device according to a modification.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, some embodiments of a semiconductor element and a semiconductor device including the semiconductor element according to the present disclosure will be described with reference to the accompanying drawings. It should be noted that, for simplicity and clarity of explanation, constituent elements shown in the drawings are not necessarily drawn to scale. Further, hatching lines may be omitted in cross-sectional views to facilitate understanding. The accompanying drawings merely illustrate embodiments of the present disclosure and should not be considered as limiting the present disclosure.

The following detailed description includes devices, systems, and methods embodying exemplary embodiments of the present disclosure. This detailed description is merely for illustrative purposes and is not intended to limit the embodiments of the present disclosure or applications and uses of such embodiments.

### First Embodiment

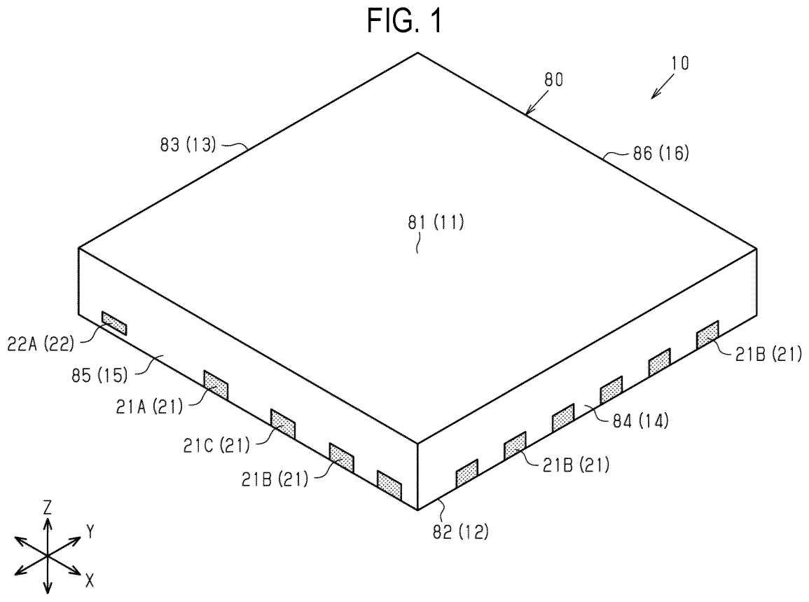

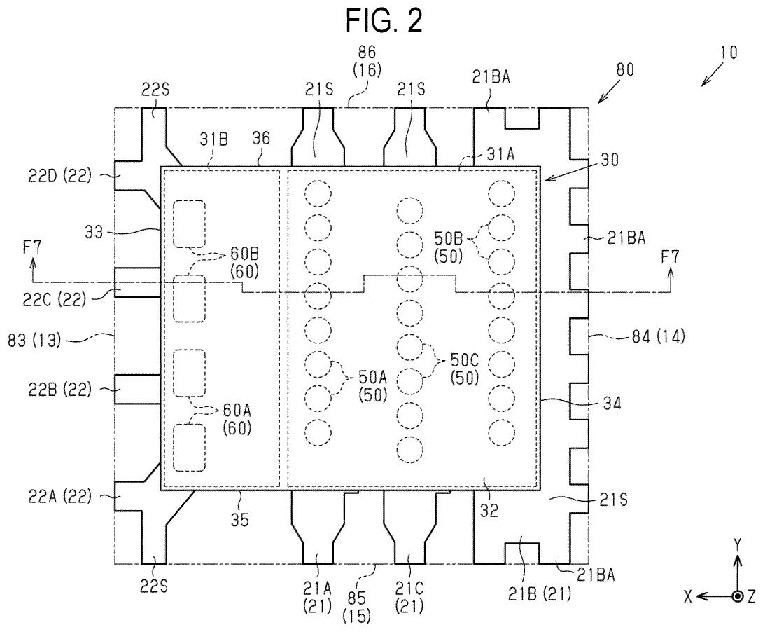

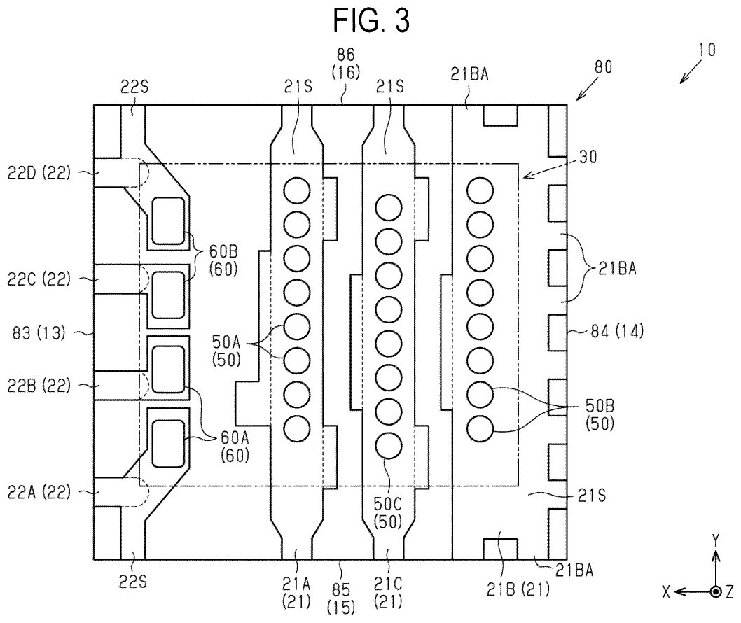

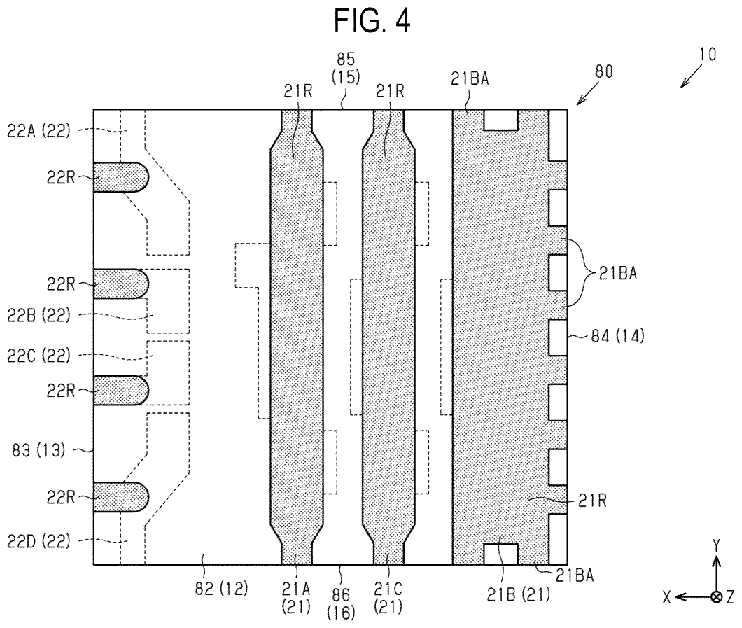

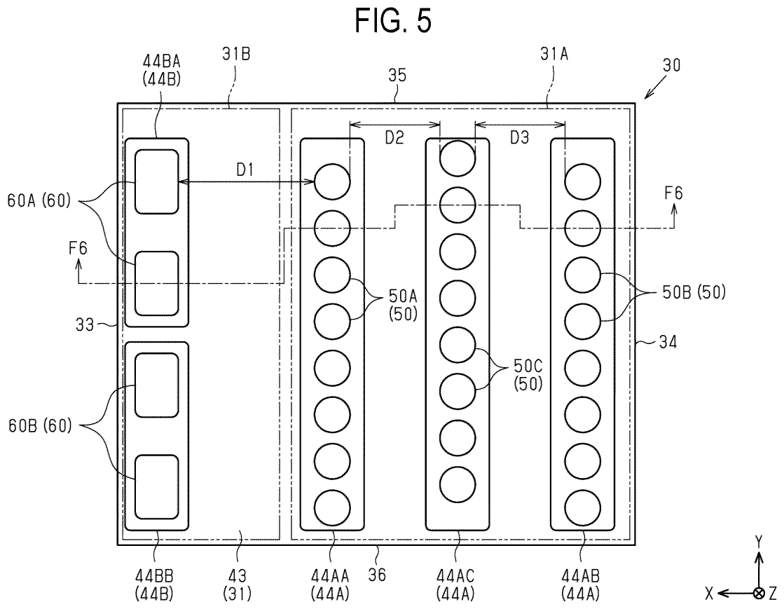

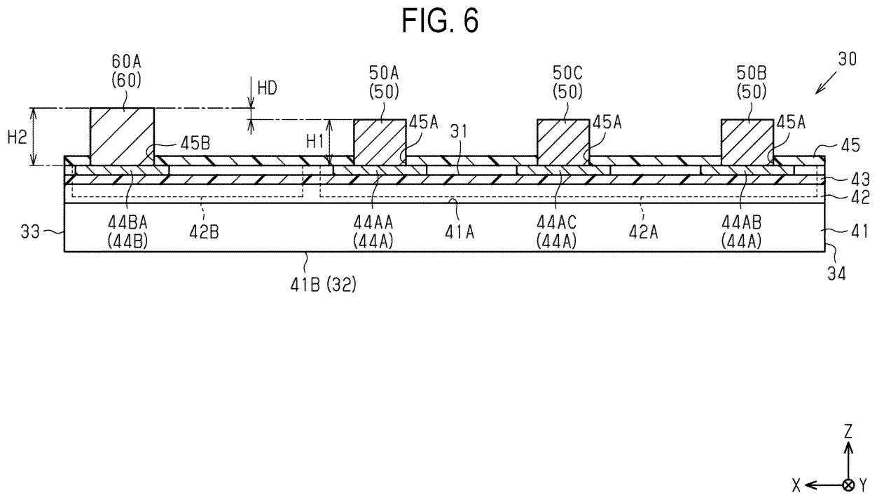

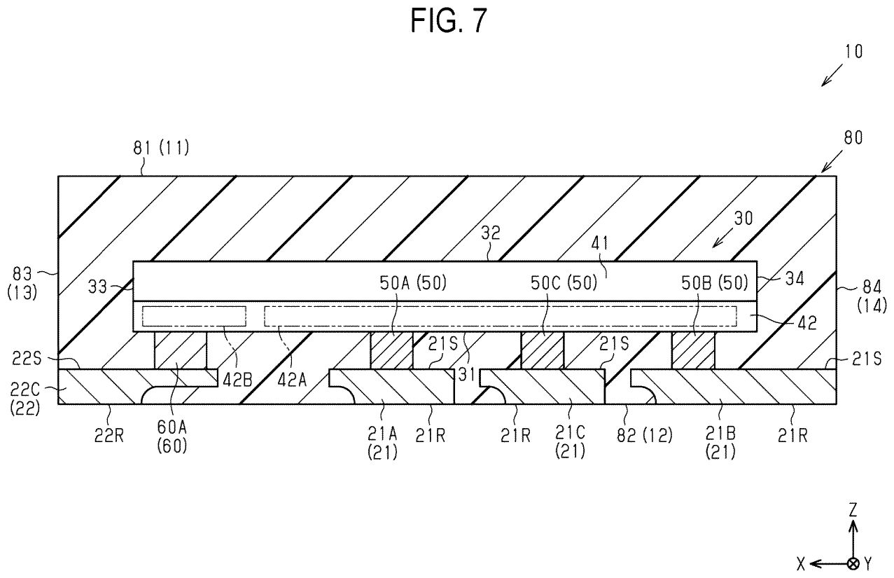

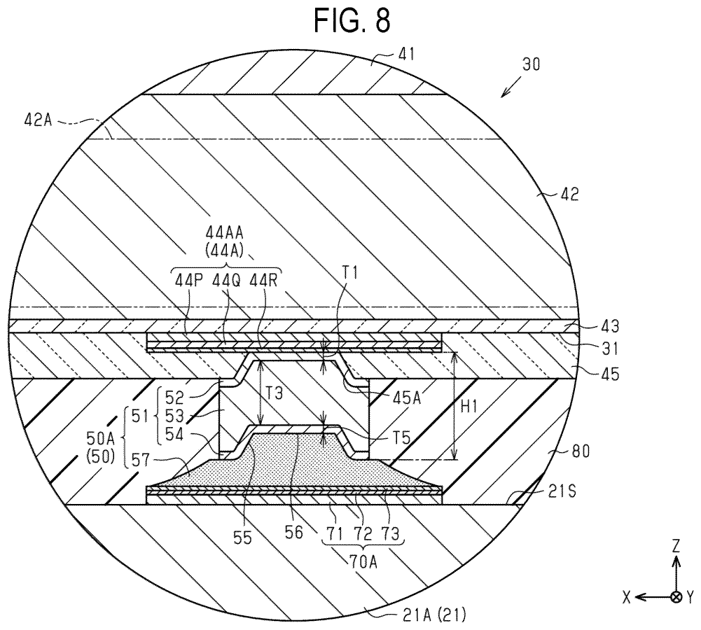

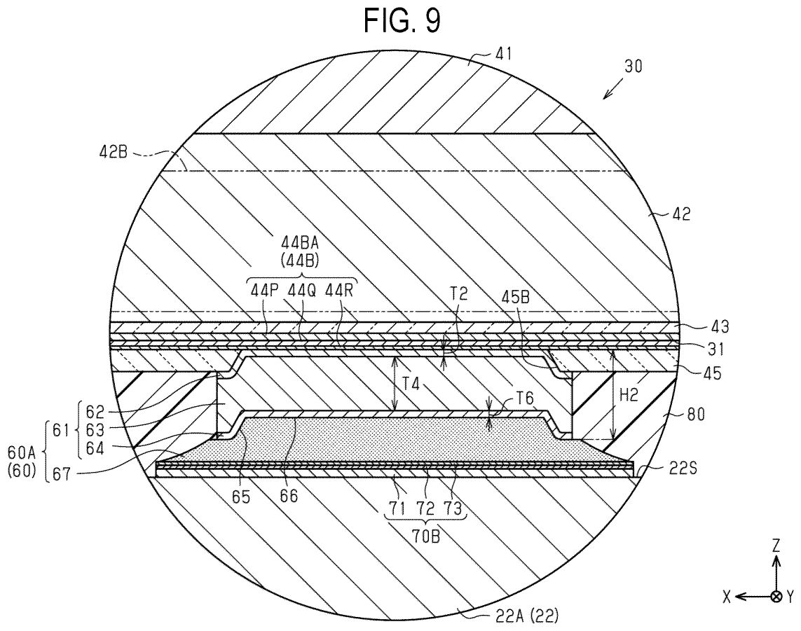

A semiconductor device 10 according to a first embodiment of the present disclosure will be described with reference to FIGS. 1 to 9. FIG. 1 shows a perspective structure of the semiconductor device 10 according to the first embodiment. FIG. 2 shows a planar structure of the semiconductor device 10 of FIG. 1 from which a sealing resin 80, which will be described later, is removed. FIG. 3 shows a planar structure of a first lead 21 and a second lead 22, which will be described later, of the semiconductor device 10. FIG. 4 shows a backside structure of the semiconductor device 10. FIG. 5 shows a planar structure of a semiconductor element 30, which will be described later, of the semiconductor device 10. FIG. 6 shows a schematic cross-sectional structure of the semiconductor element 30 taken along line F6-F6 in FIG. 5. FIG. 7 shows a schematic cross-sectional structure of the semiconductor device 10 taken along line F7-F7 in FIG. 2. FIG. 8 shows a schematic cross-sectional structure of a first electrode terminal 50 and its surroundings, which will be described later, of the semiconductor element 30. FIG. 9 shows a schematic cross-sectional structure of a second electrode terminal 60 and its surroundings, which will be described later, of the semiconductor element 30. In addition, in FIG. 2, the sealing resin 80 is indicated by a two-dot chain line for ease of understanding the figure. In FIG. 3, the semiconductor element 30 is indicated by a two-dot chain line for ease of understanding the figure. Further, the term “plan view” used in the present disclosure refers to viewing the semiconductor device 10 in a Z direction of mutually orthogonal X axis, Y axis, and Z axis shown in FIG. 1. Here, an X direction is an example of a “first direction,” and a Y direction is an example of a “second direction.”

### [Overall Configuration of Semiconductor Device]

An overall configuration of the semiconductor device 10 will be described with reference to FIGS. 1 to 4. As shown in FIG. 1, the semiconductor device 10 is formed in a rectangular flat plate shape with a Z direction as a thickness direction. The semiconductor device 10 has a device front surface 11 and a device back surface 12 facing opposite sides from each other in the Z direction, and four device side surfaces 13 to 16 which connect the device front surface 11 and the device back surface 12 in the Z direction. The device side surfaces 13 and 14 constitute both end surfaces of the semiconductor device 10 in the X direction, and the device side surfaces 15 and 16 constitute both end surfaces of the semiconductor device 10 in the Y direction. In the example shown in FIG. 1, the semiconductor device 10 is formed in a square shape in a plan view. The semiconductor device 10 is in a surface-mounting package format in which the device back surface 12 becomes a mounting surface, for example, when the semiconductor device 10 is mounted on a circuit board (not shown). In the example shown in FIG. 1, the package format of the semiconductor device 10 is a Quad Flat Non-leaded Package (QFN) type. The shape of the semiconductor device 10 in a plan view is not limited to the square shape and may be arbitrarily changed. Dimensions of the semiconductor device 10 in the X direction, the Y direction, and the Z direction may be arbitrarily changed. Further, the package format of the semiconductor device 10 is not limited to the QFN and may be arbitrarily changed.

The semiconductor device 10 may be constituted as, for example, a power conversion device such as a DC/DC converter or an AC/DC converter. In the first embodiment, the semiconductor device 10 is constituted as a DC/DC converter.

As shown in FIGS. 2 and 3, the semiconductor device 10 includes a plurality of first leads 21 (three first leads 21 in the first embodiment), a plurality of second leads 22 (four second leads 22 in the first embodiment), a semiconductor element 30 arranged on the plurality of first leads 21 and the plurality of second leads 22, and a sealing resin 80 which seals the plurality of first leads 21, the plurality of second leads 22, and the semiconductor element 30. The plurality of first leads 21 and the plurality of second leads 22 include portions exposed from the sealing resin 80. In FIGS. 1 and 4, each of the plurality of first leads 21 and the plurality of second leads 22 exposed from the sealing resin 80 is marked with dots.

As shown in FIG. 1, the sealing resin 80 constitutes an external structure of the semiconductor device 10. More specifically, the sealing resin 80 is formed in a rectangular flat plate shape with the Z direction as a thickness direction. The sealing resin 80 has a sealing front surface 81 and a sealing back surface 82 facing opposite sides from each other in the Z direction, and four sealing side surfaces 83 to 86 which connect the sealing front surface 81 and the sealing back surface 82 in the Z direction. The sealing front surface 81 constitutes the device front surface 11, and the sealing back surface 82 constitutes the device back surface 12. The sealing side surface 83 constitutes the device side surface 13, the sealing side surface 84 constitutes the device side surface 14, the sealing side surface 85 constitutes the device side surface 15, and the sealing side surface 86 constitutes the device side surface 16. Further, the sealing resin 80 supports the plurality of first leads 21 and the plurality of second leads 22.

As shown in FIGS. 2 and 3, each first lead 21 and each second lead 22 are made of a conductive material. As the conductive material, a material including one or more appropriately selected from, for example, the group of Ti (titanium), TiN (titanium nitride), Au (gold), Ag (silver), Cu (copper), Al (aluminum), and W (tungsten) is used.

Each first lead 21 and each second lead 22 are formed, for example, by etching a metal plate. A method of forming each first lead 21 and each second lead 22 may be changed arbitrarily. In an example, each first lead 21 and each second lead 22 may be formed by subjecting a metal plate to punching, bending, or the like. Hereinafter, the plurality of first leads 21 are referred to as “first leads 21A to 21C,” and the plurality of second leads 22 are referred to as “second leads 22A to 22D.”

The first lead 21A and the first lead 21B are configured to input DC power (voltage) to be subjected to power conversion in the semiconductor device 10. In the first embodiment, the first lead 21A is a positive electrode (P terminal), and the first lead 21B is a negative electrode (N terminal). The first lead 21C is configured to output AC power (voltage) converted by a switching circuit 42A (see FIG. 7) of the semiconductor element 30, which will be described later.

As shown in FIG. 3, the first leads 21A to 21C are arranged to be spaced apart from each other in the X direction, when viewed in a plan view. The first lead 21A is arranged to be closer to the sealing side surface 83 than the first leads 21B and 21C. The first lead 21B is arranged to be closer to the sealing side surface 84 than the first leads 21A and 21C.

The first leads 21A to 21C are formed in a strip shape extending in the Y direction across the sealing side surface 85 and the sealing side surface 86 in a plan view. Therefore, the first leads 21A to 21C are exposed from the sealing side surface 85 and the sealing side surface 86. The first lead 21B includes a plurality of protrusions 21BA which protrude toward any of the sealing side surfaces 84 to 86 in a plan view. The plurality of protrusions 21BA are arranged to be spaced apart from each other in the Y direction. The plurality of protrusions 21BA are exposed from the sealing side surfaces 84 to 86.

As shown in FIGS. 3 and 4, the first leads 21A to 21C each have first lead front surfaces 21S and first lead back surfaces 21R facing opposite sides from each other in the Z direction. The first lead front surface 21S faces the same side as the sealing front surface 81, and the first lead back surface 21R faces the same side as the sealing back surface 82. The first lead front surface 21S is covered with the sealing resin 80. On the other hand, the first lead back surface 21R is exposed from the sealing back surface 82. The semiconductor element 30 is supported by the first lead front surfaces 21S of the first leads 21A to 21C.

In each of the first leads 21A to 21C, an area of the first lead front surface 21S is larger than an area of the first lead back surface 21R in a plan view. Therefore, each of the first leads 21A to 21C includes at least one anchor portion where the first lead front surface 21S and the first lead back surface 21R do not overlap in a plan view. Such an anchor portion may be formed, for example, by half-etching from the first lead back surface 21R. Each of the first leads 21A to 21C includes the anchor portion to prevent the first leads 21A to 21C from falling off from the sealing back surface 82 of the sealing resin 80.

For example, Sn (tin) plating may be applied to each of the first lead back surfaces 21R of the first leads 21A to 21C and portions of the first leads 21A to 21C exposed from the sealing side surfaces 84 to 86. Instead of the Sn plating, for example, a plurality of metal platings in which Ni (nickel), Pd (palladium), and Au (gold) are laminated in this order may be used.

The second leads 22A to 22D constitute one of a ground terminal of a control circuit 42B, which will be described later, of the semiconductor element 30, a terminal into which power (voltage) for driving the control circuit 42B is input, and a terminal into which an electrical signal for transmitting to the control circuit 42B (see FIG. 7) is input.

As shown in FIG. 3, the second leads 22A to 22D are arranged to be closer to the sealing side surface 83 than the first leads 21A to 21C. The second leads 22A to 22D are arranged to be spaced apart from each other in the Y direction, for example. In an example, the second leads 22A to 22D are arranged so as to overlap each other when viewed from the Y direction.

As shown in FIGS. 3 and 4, the second leads 22A to 22D each have second lead front surfaces 22S and second lead back surfaces 22R facing opposite sides from each other in the Z direction. The second lead front surface 22S faces the same side as the first lead front surface 21S, and the second lead back surface 22R faces the same side as the first lead back surface 21R. The semiconductor element 30 is supported by the second lead front surfaces 22S of the second leads 22A to 22D. The second lead back surface 22R is exposed from the sealing back surface 82 of the sealing resin 80. Each of the second leads 22A to 22D includes a portion exposed from the sealing side surface 83 of the sealing resin 80.

In each of the second leads 22A to 22D, an area of the second lead front surface 22S is larger than an area of the second lead back surface 22R in a plan view. Therefore, each of the second leads 22A to 22D includes at least one anchor portion where the second lead front surface 22S and the second lead back surface 22R do not overlap in a plan view. Such an anchor portion may be formed, for example, by half-etching from the second lead back surface 22R. Each of the second leads 22A to 22D includes the anchor portion to prevent the second leads 22A to 22D from falling off the sealing back surface 82 of the sealing resin 80.

For example, Sn plating may be applied to each of the second lead back surfaces 22R of the second leads 22A to 22D and portions of the second leads 22A to 22D exposed from the sealing side surface 83. Instead of the Sn plating, for example, a plurality of metal platings in which Ni, Pd, and Au are laminated in this order may be used.

As shown in FIG. 2, the semiconductor element 30 is arranged at the center of the semiconductor device 10 in a plan view. The semiconductor element 30 is formed in a rectangular flat plate shape with the Z direction as a thickness direction. The semiconductor element 30 has an element front surface 31 (see FIG. 5), an element back surface 32 facing an opposite side from the element front surface 31, and element side surfaces 33 to 36 which connect the element front surface 31 and the element back surface 32 in the Z direction. The element front surface 31 faces the same side as the sealing back surface 82, and the element back surface 32 faces the same side as the sealing front surface 81. Therefore, the element front surface 31 faces the first lead front surfaces 21S of the first leads 21A to 21C and the second lead front surfaces 22S of the second leads 22A to 22D in the Z direction. The element side surface 33 faces the same side as the sealing side surface 83, the element side surface 34 faces the same side as the sealing side surface 84, the element side surface 35 faces the same side as the sealing side surface 85, and the element side surface 36 faces the same side as the sealing side surface 86.

The element front surface 31 includes a first region 31A and a second region 31B. The first region 31A and the second region 31B are arranged in the X direction. The first region 31A is arranged to be closer to the element side surface 34 than the second region 31B. The first region 31A and the second region 31B are rectangular regions in a plan view. An area of the first region 31A is larger than an area of the second region 31B. In an example, the area of the first region 31A is approximately twice the area of the second region 31B.

The first region 31A is a region of the element front surface 31 that faces the first leads 21A to 21C in the Z direction. Therefore, the first region 31A may be said to be a region that electrically connects the first leads 21A to 21C and the semiconductor element 30. The second region 31B is a region of the element front surface 31 that faces the second leads 22A to 22D in the Z direction. Therefore, the second region 31B may be said to be a region that electrically connects the second leads 22A to 22D and the semiconductor element 30.

The second region 31B is a region of the element front surface 31 that is closer to the element side surface 33 than the first leads 21A to 21C. In an example, of both ends of the second region 31B in the X direction, one end closer to the first region 31A is located at a position adjacent to the first lead 21A in the X direction when viewed in a plan view.

As shown in FIG. 6, the semiconductor element 30 includes a semiconductor substrate 41, a semiconductor layer 42, a passivation film 43, a first electrode 44A, a second electrode 44B, an insulating layer 45, a plurality of first electrode terminals 50, and a plurality of second electrode terminals 60. The semiconductor layer 42, the passivation film 43, the first electrode 44A, the second electrode 44B, the insulating layer 45, the plurality of first electrode terminals 50, and the plurality of second electrode terminals 60 are provided over the semiconductor substrate 41. The semiconductor element 30 is a flip-chip type large scale integration (LSI) in which circuits are constituted.

The semiconductor substrate 41 is formed in a rectangular flat plate shape with the Z direction as a thickness direction. The semiconductor substrate 41 is formed of a material containing, for example, Si (silicon) or SiC (silicon carbide). The semiconductor substrate 41 has a substrate front surface 41A and a substrate back surface 41B facing opposite sides from each other in the Z direction. The substrate front surface 41A faces the same side as the element front surface 31, and the substrate back surface 41B faces the same side as the element back surface 32. In an example, the substrate back surface 41B constitutes the element back surface 32.

The semiconductor layer 42 is formed over the substrate front surface 41A. The semiconductor layer 42 includes a plurality of types of p-type semiconductors and n-type semiconductors based on a difference in an amount of doped elements. A switching circuit 42A and a control circuit 42B electrically connected to the switching circuit 42A are formed in the semiconductor layer 42. In other words, the semiconductor element 30 includes the switching circuit 42A and the control circuit 42B.

The switching circuit 42A is a circuit including switching elements constituted by semiconductors, such as a metal-oxide-semiconductor field-effect transistor (MOSFET) and an insulated gate bipolar transistor (IGBT). In an example, the switching circuit 42A is divided into two regions: a high voltage region (upper arm circuit) and a low voltage region (lower arm circuit). Each of the high voltage region and the low voltage region is constituted by at least one transistor. In an example, the transistor is constituted by an n-channel MOSFET.

The switching circuit 42A is formed in the first region 31A. In other words, the first region 31A is a region in which a first transistor and a second transistor connected in series are formed. Here, the at least one transistor formed in the high voltage region (upper arm circuit) is an example of the first transistor, and the at least one transistor formed in the low voltage region (lower arm circuit) is an example of the second transistor.

The control circuit 42B includes, for example, a gate driver configured to drive the switching circuit 42A, a bootstrap circuit corresponding to the high voltage region of the switching circuit 42A, and the like. The control circuit 42B is configured to perform control for driving the switching circuit 42A. The control circuit 42B may be said to be a circuit configured to control the first transistor and the second transistor. The control circuit 42B is formed in the second region 31B. The semiconductor layer 42 further includes a wiring layer (not shown). The wiring layer is configured to electrically connect the switching circuit 42A and the control circuit 42B, for example.

The passivation film 43 has electrical insulation properties and is formed to cover the semiconductor layer 42. The passivation film 43 has a laminated structure of, for example, a SiO₂ (silicon oxide) film and a SiN (silicon nitride) film. In an example, a surface of the passivation film 43 constitutes the element front surface 31.

As shown in FIG. 5, the first electrode 44A and the second electrode 44B are formed in the element front surface 31. That is, the first electrode 44A and the second electrode 44B are formed over the passivation film 43. A plurality of first electrodes 44A and a plurality of second electrodes 44B are provided. The plurality of first electrodes 44A are formed in the first region 31A of the element front surface 31. The plurality of first electrodes 44A are electrically connected to the switching circuit 42A. The plurality of second electrodes 44B are formed in the second region 31B of the element front surface 31. The plurality of second electrodes 44B are electrically connected to the control circuit 42B.

The plurality of first electrodes 44A are formed according to the number of first leads 21. In the first embodiment of the present disclosure, three first electrodes 44A are formed corresponding to the first leads 21A to 21C (see FIG. 3) which are three first leads 21. For the sake of convenience, these three first electrodes 44A are referred to as a “first electrode 44AA,” a “first electrode 44AB,” and a “first electrode 44AC.”

The first electrodes 44AA to 44AC are arranged to be spaced apart from each other in the X direction. Each of the first electrodes 44AA to 44AC is formed in a strip shape extending in the Y direction in a plan view. In an example, dimensions of the first electrodes 44AA to 44AC in the Y direction are equal to each other. The first electrodes 44AA to 44AC face the first leads 21A to 21C, respectively, in the Z direction. More specifically, the first electrode 44AA faces the first lead 21A in the Z direction, the first electrode 44AB faces the first lead 21B in the Z direction, and the first electrode 44AC faces the first lead 21C in the Z direction.

The first electrode 44AA is electrically connected to the first lead 21A via a plurality of first electrode terminals 50. The first electrode 44AB is electrically connected to the first lead 21B via another plurality of first electrode terminals 50. The first electrode 44AC is electrically connected to the first lead 21C via yet another plurality of first electrode terminals 50. As a result, the switching circuit 42A is electrically connected to the first leads 21A to 21C. A configuration and an arrangement aspect of first electrode terminals 50 and a connection structure between the first leads 21A to 21C and the plurality of first electrodes 44A will be described later. Further, for the sake of convenience, a first electrode terminal 50 connected to the first electrode 44AA is referred to as a “first electrode terminal 50A,” a first electrode terminal 50 connected to the first electrode 44AB is referred to as a “first electrode terminal 50B,” and a first electrode terminal 50 connected to the first electrode 44AC is referred to as a “first electrode terminal 50C.”

The plurality of second electrodes 44B are formed according to the number of second leads 22. In the first embodiment, two second electrodes 44B are formed corresponding to the second leads 22A to 22D (see FIG. 3) which are four second leads 22. For the sake of convenience, these two second electrodes 44B are referred to as a “second electrode 44BA” and a “second electrode 44BB,” respectively.

In an example, the second electrode 44BA faces the second leads 22A and 22B in the Z direction, and the second electrode 44BB faces the second leads 22C and 22D in the Z direction. In the first embodiment, the second electrodes 44BA and 44BB are arranged at the same position in the X direction and spaced apart from each other in the Y direction. The second electrodes 44BA and 44BB are formed in a rectangular shape with the Y direction being a longitudinal direction and the X direction being a lateral direction, when viewed in a plan view.

The second electrode 44BA is electrically connected to the second leads 22A and 22B via a plurality of second electrode terminals 60. The second electrode 44BB is electrically connected to the second leads 22C and 22D via another plurality of second electrode terminals 60. As a result, the control circuit 42B is electrically connected to the second leads 22A to 22D. A configuration and an arrangement aspect of second electrode terminals 60 and a connection structure between the second leads 22A to 22D and the plurality of second electrodes 44B will be described later. Further, for the sake of convenience, a second electrode terminal 60 connected to the second electrode 44BA is referred to as a “second electrode terminal 60A,” and a second electrode terminal 60 connected to the second electrode 44BB is referred to as a “second electrode terminal 60B.”

In the following description, when the first electrodes 44A are used without distinguishing the first electrodes 44AA to 44AC from one another, the first electrodes 44A are simply referred to as a first electrode 44A, and when the second electrodes 44B are used without distinguishing the second electrodes 44BA and 44BB from each other, the second electrodes 44B are simply referred to as a second electrode 44B. Further, when the first electrode terminals 50 are used without distinguishing the first electrode terminals 50A to 50C from one another, the first electrode terminals 50 are simply referred to as a first electrode terminal 50, and when the second electrode terminals 60 are used without distinguishing the second electrode terminals 60A and 60B from each other, the second electrode terminals 60 are simply referred to as a second electrode terminal 60.

As shown in FIG. 6, the insulating layer 45 is formed in the element front surface 31. The insulating layer 45 partially covers the passivation film 43, each first electrode 44A, and each second electrode 44B. The insulating layer 45 is formed of an insulating material such as phenol resin or polyimide resin. The insulating layer 45 includes a plurality of first openings 45A (three first openings 45A in the first embodiment) and a plurality of second openings 45B (two second openings 45B in the first embodiment). The plurality of first openings 45A individually expose the first electrodes 44AA to 44AC. The plurality of second openings 45B individually expose the second electrodes 44BA and 44BB (see FIG. 5).

The first electrode terminals 50A to 50C are individually provided within the plurality of first openings 45A. The first electrode terminal 50A is electrically connected to the first electrode 44AA exposed from one first opening 45A. As shown in FIG. 5, a plurality of first electrode terminals 50A are provided. The plurality of first electrode terminals 50A are arranged at the same position in the X direction and spaced apart from each other in the Y direction.

As shown in FIG. 6, the first electrode terminal 50B is electrically connected to the first electrode 44AB exposed from another first opening 45A. As shown in FIG. 5, a plurality of first electrode terminals 50B are provided. The plurality of first electrode terminals 50B are arranged at the same position in the X direction and spaced apart from each other in the Y direction.

As shown in FIG. 6, the first electrode terminal 50C is electrically connected to the first electrode 44AC exposed from yet another first opening 45A. As shown in FIG. 5, a plurality of first electrode terminals 50C are provided. The plurality of first electrode terminals 50C are arranged at the same position in the X direction and spaced apart from each other in the Y direction. In an example, the numbers of first electrode terminals 50A to 50C are the same. The number of each of the first electrode terminals 50A to 50C may be changed arbitrarily.

In this way, the first electrode terminals 50A to 50C are electrically connected to the switching circuit 42A (see FIG. 6). In other words, it may be said that the first electrode terminals 50A to 50C are electrically connected to the first transistor and the second transistor. In an example, the first electrode terminal 50A is electrically connected to a drain of the first transistor. The first electrode terminal 50B is electrically connected to a source of the second transistor. The first electrode terminal 50C is electrically connected to a source of the first transistor and a drain of the second transistor.

As shown in FIG. 6, the plurality of second electrode terminals 60 are individually provided within the plurality of second openings 45B. The second electrode terminal 60A is electrically connected to the second electrode 44BA exposed from one second opening 45B. A plurality of second electrode terminals 60A (two second electrode terminals 60A in the first embodiment) are provided. The second electrode terminal 60B is electrically connected to a second electrode 44BB (see FIG. 5) exposed from another second opening 45B. A plurality of second electrode terminals 60B (two second electrode terminals 60B in the first embodiment) are provided. As shown in FIG. 5, the plurality of second electrode terminals 60B are arranged at the same position in the X direction and spaced apart from each other in the Y direction. In this way, the second electrode terminals 60A and 60B are electrically connected to the control circuit 42B (see FIG. 6).

The plurality of first electrode terminals 50 and the plurality of second electrode terminals 60 are provided over the side of the element front surface 31 in the Z direction. As shown in FIG. 7, the semiconductor element 30 is arranged such that the element front surface 31 faces the plurality of first leads 21A to 21C and the plurality of second leads 22A to 22D. Therefore, each first electrode terminal 50 protrudes from the element front surface 31 toward the first leads 21A to 21C in the Z direction. Each second electrode terminal 60 protrudes from the element front surface 31 toward the second leads 22A to 22D in the Z direction.

[Configuration of Surroundings of Electrodes of Semiconductor Element and Connection Structure between Electrode Terminals and Leads]

Configurations of each first electrode 44A, each second electrode 44B, and their surroundings of the semiconductor element 30 and a connection structure between the semiconductor element 30 and the first leads 21A to 21C and between the semiconductor element 30 and the second leads 22A to 22D will be described with reference to FIGS. 2 and 7 to 9.

As shown in FIG. 8, each first electrode 44A is electrically connected to a wiring layer (not shown) provided in the semiconductor layer 42 through an opening (not shown) formed in the passivation film 43. As a result, each first electrode 44A is electrically connected to the switching circuit 42A.

Each first electrode 44A is constituted by a plurality of metal layers laminated from the passivation film 43 toward an opposite side from the semiconductor layer 42. Each first electrode 44A includes a first metal layer 44P, a second metal layer 44Q, and a third metal layer 44R. The first metal layer 44P is in contact with the passivation film 43. The first metal layer 44P is formed of a material containing, for example, Cu. The second metal layer 44Q is laminated on the first metal layer 44P. The second metal layer 44Q is formed of a material containing, for example, Ni. The third metal layer 44R is laminated on the second metal layer 44Q. The third metal layer 44R is formed of a material containing, for example, Pd. The configuration and material of each first electrode 44A may be changed arbitrarily.

As shown in FIG. 9, each second electrode 44B is electrically connected to a wiring layer (not shown) provided in the semiconductor layer 42 through an opening (not shown) formed in the passivation film 43. As a result, each second electrode 44B is electrically connected to the control circuit 42B. The configuration of each second electrode 44B is the same as the configuration of each first electrode 44A. Therefore, constituent elements of each second electrode 44B are denoted by the same reference numerals as constituent elements of each first electrode 44A, and detailed explanation thereof will be omitted.

As shown in FIG. 8, the first electrode terminal 50A electrically connected to the first electrode 44A exposed from the first opening 45A of the insulating layer 45 includes a first portion buried in the first opening 45A and a second portion protruding from the insulating layer 45. The second portion includes a portion that overlaps the insulating layer 45 at the periphery of the first opening 45A in a plan view.

The first electrode terminal 50 includes a first pillar portion 51 and a first solder portion 57. The first pillar portion 51 is a portion in contact with the first electrode 44A. The first solder portion 57 is provided at a tip portion of the first pillar portion 51. The first pillar portion 51 includes the first portion and the second portion.

The first pillar portion 51 includes a first seed layer 52, a first plating layer 53, and a first front surface side plating layer 54. The first pillar portion 51 has a structure in which the first seed layer 52, the first plating layer 53, and the first front surface side plating layer 54 are laminated in this order from the side of the first electrode 44A.

The first seed layer 52 is in contact with the first electrode 44A and the insulating layer 45. The first seed layer 52 is formed of a material containing, for example, Cu. The first seed layer 52 is formed, for example, by electroless plating. The material and a method of forming the first seed layer 52 may be changed arbitrarily. In an example, the first seed layer 52 may be formed by a sputtering method.

The first plating layer 53 is in contact with the first seed layer 52. The first plating layer 53 is formed of a material containing, for example, Cu. The first plating layer 53 is formed by electrolytic plating. The material and a method of forming the first plating layer 53 may be changed arbitrarily.

The first front surface side plating layer 54 is in contact with the first plating layer 53. The first front surface side plating layer 54 functions to suppress a chemical combination reaction between the first plating layer 53 and the first solder portion 57 by being interposed between the first plating layer 53 and the first solder portion 57. Therefore, for the first front surface side plating layer 54, a metal material that can suppress the chemical combination reaction is appropriately selected. Examples of this metal material may include Ni, Fe (iron), and the like. In an example, when the first plating layer 53 contains Cu and the first solder portion 57 contains Sn, the first front surface side plating layer 54 may be formed of a material containing Ni. The first front surface side plating layer 54 is formed, for example, by electrolytic plating. The material and a method of forming the first front surface side plating layer 54 may be changed arbitrarily. A first recess 55 having a central portion, which is recessed from a peripheral portion thereof, is formed in a tip surface 56 of the first pillar portion 51. Here, the tip surface 56 of the first pillar portion 51 is a surface on an opposite side from the first electrode 44A in the Z direction and is a surface in contact with the first solder portion 57.

The first solder portion 57 electrically connects the first pillar portion 51 and the first lead by being interposed between the first pillar portion 51 and one of the first leads 21A to 21C that the first pillar portion 51 faces. In FIG. 8, the first solder portion 57 electrically connects the first pillar portion 51 and the first lead 21A. The first solder portion 57 is formed of, for example, solder (SnAg, etc.) containing Sn.

A first plating layer 70A is interposed between the first solder portion 57 and the first lead front surface 21S of the first leads 21A to 21C in the Z direction. The first plating layer 70A electrically connects the first solder portion 57 and the first leads 21A to 21C. The first plating layer 70A functions to suppress a chemical combination reaction between the first leads 21A to 21C and the first solder portion 57. The material of the first plating layer 70A is not particularly limited, and any metal material that can suppress the chemical combination reaction may be selected as appropriate. Examples of the metal material may include Ni, Fe, and the like. In the example shown in FIG. 8, the first plating layer 70A is provided so as to partially cover the first lead front surface 21S.

The first plating layer 70A includes a laminated structure of a first layer 71, a second layer 72, and a third layer 73. The first layer 71 is laminated on the first lead front surface 21S of the first leads 21A to 21C. In an example, when the first leads 21A to 21C contain Cu and the first solder portion 57 contains Sn, the first layer 71 contains Ni. The second layer 72 is laminated on the first layer 71. The material of the second layer 72 includes, for example, Pd. The third layer 73 is laminated on the second layer 72. The third layer 73 is in contact with the first solder portion 57, for example. The material of the third layer 73 includes, for example, Au. The materials of the first to third layers 71 to 73 may be changed arbitrarily.

As shown in FIG. 9, the second electrode terminal 60 electrically connected to the second electrode 44B exposed from the second opening 45B of the insulating layer 45 includes a first portion buried in the second opening 45B and a second portion protruding from the insulating layer 45. The second portion includes a portion that overlaps the insulating layer 45 at the periphery of the second opening 45B in a plan view. The configuration of the second electrode terminal 60 is the same as the configuration of the first electrode terminal 50. That is, the second electrode terminal 60 includes a second pillar portion 61 and a second solder portion 67. The second pillar portion 61 includes a second seed layer 62, a second plating layer 63, and a second front surface side plating layer 64. A second recess 65 is provided in the second pillar portion 61. The second solder portion 67 is provided over a tip surface 66 of the second pillar portion 61. Since the constituent elements of the second electrode terminal 60 are the same as the constituent elements of the first electrode terminal 50, detailed explanation thereof will be omitted.

The second solder portion 67 of the second electrode terminal 60 electrically connects the second pillar portion 61 and the second lead by being interposed between the second pillar portion 61 and one of the second leads 22A to 22D that the second pillar portion 61 faces. In FIG. 9, the second solder portion 67 electrically connects the second pillar portion 61 and the second lead 22C.

A second plating layer 70B is interposed between the second solder portion 67 and the second lead front surface 22S of the second leads 22A to 22D in the Z direction. The second plating layer 70B electrically connects the second solder portion 67 and the second leads 22A to 22D. The second plating layer 70B functions to suppress the chemical combination reaction between the second leads 22A to 22D and the second solder portion 67. The material of the second plating layer 70B is not particularly limited, and any metal material that can suppress the chemical combination reaction may be selected as appropriate. Examples of the metal material may include Ni, Fe, and the like. In the example shown in FIG. 9, the second plating layer 70B is provided so as to partially cover the second lead front surface 22S. The configuration of the second plating layer 70B is the same as the configuration of the first plating layer 70A. Therefore, the same constituent elements in the second plating layer 70B as in the first plating layer 70A are denoted by the same reference numerals, and the explanation thereof will be omitted.

### [Configuration and Arrangement Aspect of Electrode Terminals of Semiconductor Element]

Configurations and arrangement aspects of the first electrode terminal 50 and the second electrode terminal 60 will be described with reference to FIGS. 5 and 6.

As shown in FIG. 5, a plurality of first electrode terminals 50 (twenty-four first electrode terminals 50 in the first embodiment) are arranged in the first region 31A. A plurality of second electrode terminals 60 (four second electrode terminals 60 in the first embodiment) are arranged in the second region 31B. A ratio of an area of the second region 31B to an area of the first region 31A is smaller than a ratio of the number of second electrode terminals 60 to the number of first electrode terminals 50. Therefore, the number of second electrode terminals 60 per unit area in the second region 31B is smaller than the number of first electrode terminals 50 per unit area in the first region 31A. Here, the number of second electrode terminals 60 per unit area in the second region 31B can be calculated by dividing the area of the second region 31B from the number of second electrode terminals 60. The number of first electrode terminals 50 per unit area in the first region 31A can be calculated by dividing the area of the first region 31A from the number of first electrode terminals 50.

The plurality of first electrode terminals 50A, the plurality of first electrode terminals 50B, and the plurality of first electrode terminals 50C are arranged to be apart from each other in the X direction. In the example shown in FIG. 5, the plurality of second electrode terminals 60 are arranged at an end portion, which is closer to the element side surface 33, of both end portions of the element back surface 32 in the X direction.

In an example, a distance DI between the plurality of second electrode terminals 60 and the plurality of first electrode terminals 50A in the X direction is larger than a distance D2 between the plurality of first electrode terminals 50A and the plurality of first electrode terminals 50B in the X direction. Further, in an example, the distance D2 is larger than a distance D3 between the plurality of first electrode terminals 50B and the plurality of first electrode terminals 50C in the X direction.

In a plan view, the first electrode terminals 50A to 50C have the same shape, and the second electrode terminals 60A and 60B have the same shape. On the other hand, in a plan view, the shapes of the first electrode terminals 50A to 50C are different from the shapes of the second electrode terminals 60A and 60B. In the example shown in FIG. 5, the first electrode terminals 50A to 50C are formed in a circular shape in a plan view. The second electrode terminals 60A and 60B are formed in a rectangular shape in a plan view. In an example, the second electrode terminals 60A and 60B are formed in a rectangular shape with the Y direction being a longitudinal direction and the X direction being a lateral direction. In an example, areas of the second electrode terminals 60 are equal to each other in a plan view. In an example, areas of the first electrode terminals 50 are equal to each other in a plan view.

In a plan view, an area of each second electrode terminal 60 is larger than an area of each first electrode terminal 50. Here, the area of the first electrode terminal 50 in a plan view can be defined by an area of the tip surface 56 of the first pillar portion 51 of the first electrode terminal 50 in a plan view. The area of the second electrode terminal 60 can be defined by an area of the tip surface 66 of the second pillar portion 61 of the second electrode terminal 60 in a plan view.

The shape of each first electrode terminal 50 and the shape of each second electrode terminal 60 in a plan view may be changed arbitrarily. In an example, the shape of each first electrode terminal 50 in a plan view may be any one of an elliptical shape, an oval shape, a rectangular shape, and a polygonal shape. In an example, the shape of each second electrode terminal 60 in a plan view may be any one of a circular shape, an elliptical shape, an oval shape, and a polygonal shape. Further, for example, in a plan view, the shape of each first electrode terminal 50 may be the same as the shape of each second electrode terminal 60.

As shown in FIG. 6, a height dimension H2 of each second electrode terminal 60 is slightly higher than a height dimension H1 of each first electrode terminal 50. Here, the height dimension H2 of the second electrode terminal 60 can be defined by a maximum distance between the second electrode 44B and the tip surface 66 of the second pillar portion 61 of the second electrode terminal 60 in the Z direction. The height dimension H1 of the first electrode terminal 50 can be defined by a maximum distance between the first electrode 44A and the tip surface 56 of the first pillar portion 51 of the first electrode terminal 50 in the Z direction.

As shown in FIGS. 8 and 9, a thickness T1 of the first seed layer 52 of the first pillar portion 51 of the first electrode terminal 50 is, for example, equal to a thickness T2 of the second seed layer 62 of the second pillar portion 61 of the second electrode terminal 60. Here, in a case where a difference between the thickness T1 and the thickness T2 is, for example, within 10% of the thickness T1, it can be said that the thickness T1 of the first seed layer 52 is equal to the thickness T2 of the second seed layer 62. A thickness T4 of the second plating layer 63 of the second pillar portion 61 of the second electrode terminal 60 is, for example, slightly thicker than a thickness T3 of the first plating layer 53 of the first pillar portion 51 of the first electrode terminal 50. Further, a thickness T5 of the first front surface side plating layer 54 of the first electrode terminal 50 is, for example, equal to a thickness T6 of the second front surface side plating layer 64 of the second electrode terminal 60. Here, in a case where a difference between the thickness T5 and the thickness T6 is, for example, within 10% of the thickness T5, it can be said that the thickness T5 of the first front surface side plating layer 54 is equal to the thickness T6 of the second front surface side plating layer 64. In this way, based on the fact that the thickness T4 of the second plating layer 63 is slightly thicker than the thickness T3 of the first plating layer 53, the height dimension H2 of each second electrode terminal 60 is slightly higher than the height dimension H1 of each first electrode terminal 50.

Here, the height dimension H2 of each second electrode terminal 60 is changed according to an area of each second electrode terminal 60 in a plan view. That is, the height dimension H2 of each second electrode terminal 60 becomes smaller as an area of each second electrode terminal 60 in a plan view becomes larger. Therefore, by adjusting the area of each second electrode terminal 60 in a plan view, the height dimension H2 of each second electrode terminal 60 may be equal to or slightly smaller than the height dimension H1 of each first electrode terminal 50.

### [Method of Manufacturing Semiconductor Element]

An example of a general method of manufacturing the semiconductor element 30 will be described. In particular, a process of manufacturing the first electrode terminal 50 and the second electrode terminal 60 will be described in detail below.

The method of manufacturing the semiconductor element 30 includes a step of preparing the semiconductor substrate 41, a step of forming the semiconductor layer 42 and the passivation film 43 in the semiconductor substrate 41, and a step of forming the plurality of first electrodes 44A, the plurality of second electrodes 44B, and the insulating layer 45 in the semiconductor layer 42. The semiconductor substrate 41 is formed of a semiconductor wafer containing, for example, Si. In the step of forming the semiconductor layer 42, the switching circuit 42A and the control circuit 42B are formed. The passivation film 43 is formed to cover the semiconductor layer 42. Each first electrode 44A and each second electrode 44B are formed over the passivation film 43. The insulating layer 45 is formed to cover each first electrode 44A and each second electrode 44B. On the other hand, in the insulating layer 45, the first openings 45A and the second openings 45B are formed to partially expose each first electrode 44A and each second electrode 44B.

The method of manufacturing the semiconductor element 30 includes a step of forming the plurality of first electrode terminals 50 and the plurality of second electrode terminals 60. This step includes a step of forming a seed layer, a step of forming the first plating layer 53 and the second plating layer 63, a step of forming the first front surface side plating layer 54 and the second front surface side plating layer 64, a step of forming the first solder portion 57 and the second solder portion 67, and a step of forming the first seed layer 52 and the second seed layer 62.

In the step of forming the seed layer, the seed layer is formed over the entire surface of the insulating layer 45 and on each first electrode 44A and each second electrode 44B exposed from the insulating layer 45, for example, by electroless plating. The seed layer may be formed by a sputtering method.

In the step of forming the first plating layer 53 and the second plating layer 63, the first plating layer 53 and the second plating layer 63 are formed over the seed layer by electrolytic plating in which the seed layer is used as a conductive path. More specifically, a resist having openings in a region where the first plating layer 53 and the second plating layer 63 are to be formed is formed over the seed layer. Subsequently, the first plating layer 53 and the second plating layer 63 are formed over the seed layer exposed from the resist.

In the step of forming the first front surface side plating layer 54 and the second front surface side plating layer 64, the first front surface side plating layer 54 is formed over the first plating layer 53, for example, by electrolytic plating, and the second front surface side plating layer 64 is formed over the second plating layer 63, for example, by electrolytic plating.

In the step of forming the first solder portion 57 and the second solder portion 67, the first solder portion 57 is formed over the first front surface side plating layer 54 and the second solder portion 67 is formed over the second front surface side plating layer 64, for example, by electrolytic plating. Thereafter, the resist is removed.

In the step of forming the first seed layer 52 and the second seed layer 62, the first seed layer 52 and the second seed layer 62 are formed by patterning the seed layer. That is, the first seed layer 52 and the second seed layer 62 are formed by removing the seed layer exposed from the first plating layer 53 and the second plating layer 63 in a plan view. Through the above-described steps, each first electrode terminal 50 and each second electrode terminal 60 are manufactured, and the semiconductor element 30 is manufactured.

### [Operation]

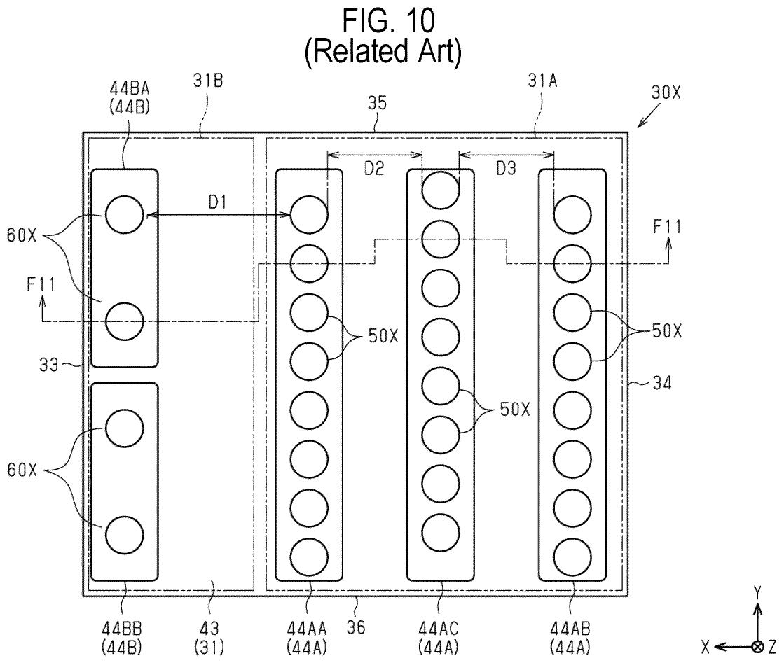

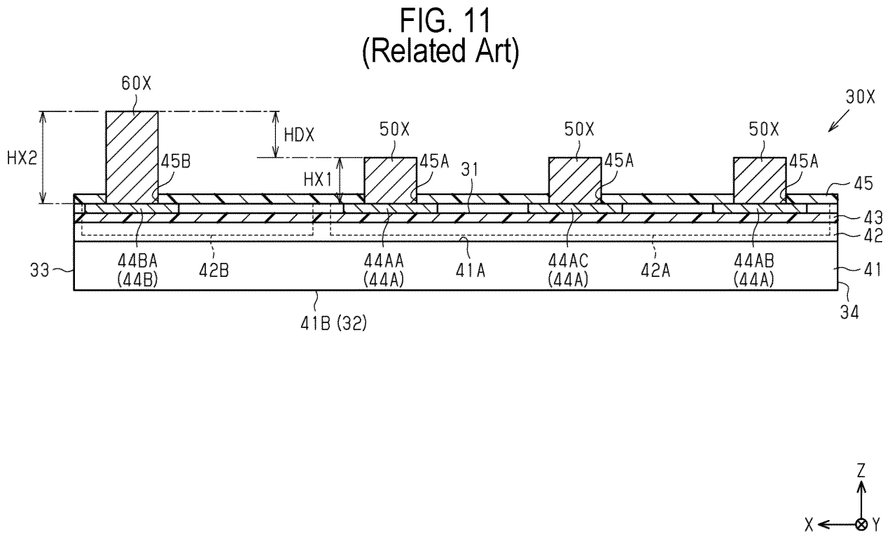

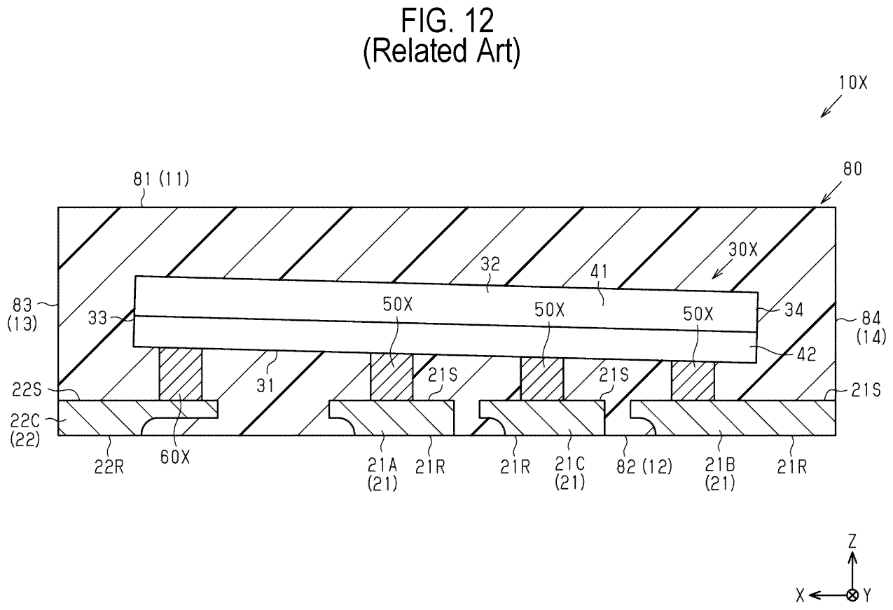

An operation of the first embodiment of the present disclosure will be described with reference to FIGS. 5 to 7 and 10 to 12. FIG. 10 shows a schematic planar structure of a semiconductor element 30X of a comparative example. FIG. 11 shows a schematic cross-sectional structure of the semiconductor element 30X taken along line F11-F11 in FIG. 10. FIG. 12 shows a schematic cross-sectional structure of a semiconductor device 10X including the semiconductor element 30X of the comparative example. In the following description, a first electrode terminal and a second electrode terminal of the semiconductor element 30X of the comparative example are referred to as a “first electrode terminal 50X” and a “second electrode terminal 60X,” respectively.

As shown in FIG. 10, in the semiconductor element 30X of the comparative example, arrangement aspects of a plurality of first electrode terminals 50X and a plurality of second electrode terminals 60X are the same as those of the plurality of first electrode terminals 50 and the plurality of second electrode terminals 60 in the first embodiment. On the other hand, in the semiconductor element 30X of the comparative example, an area of each second electrode terminal 60X in a plan view is smaller than an area of each second electrode terminal 60 (see FIG. 5) in a plan view. In an example, an area of each second electrode terminal 60X in a plan view is the same as an area of each first electrode terminal 50X in a plan view.

The plurality of first electrode terminals 50X are densely arranged in the first region 31A. Therefore, a maximum dimension of each first electrode terminal 50X in a plan view (for example, a diameter of the first electrode terminal 50X in a plan view) is larger than a distance between a predetermined first electrode terminal 50X and a first electrode terminal 50X adjacent to the predetermined first electrode terminal 50X in the Y direction.

On the other hand, the plurality of second electrode terminals 60X are arranged apart from each other in the second region 31B. Therefore, a maximum dimension of the plurality of second electrode terminals 60X in a plan view (for example, a diameter of the second electrode terminal 60X in a plan view) is smaller than a distance between a predetermined second electrode terminal 60X and a second electrode terminal 60X adjacent to the predetermined second electrode terminal 60X in the Y direction. In this way, a ratio of a total area of the plurality of second electrode terminals 60X to an area of the second region 31B is lower than a ratio of a total area of the plurality of first electrode terminals 50X to an area of the first region 31A.

The plurality of second electrode terminals 60X in the second region 31B are arranged to be spaced apart from the plurality of first electrode terminals 50X in the first region 31A. Therefore, it can be said that the plurality of second electrode terminals 60X in the second region 31B are arranged sparsely with respect to the plurality of first electrode terminals 50X in the first region 31A. Therefore, a current density in electrolytic plating when forming each first electrode terminal 50X and each second electrode terminal 60X is larger in the second electrode terminal 60X (the second electrode 44B) than in the first electrode terminal 50X (the first electrode 44A). As a result, as shown in FIG. 11, a height dimension HX2 of each second electrode terminal 60X becomes higher than a height dimension HX1 of each first electrode terminal 50X. As a result, as shown in FIG. 12, when the semiconductor element 30X is mounted on the first leads 21A to 21C and the second leads 22A to 22D, due to variations in the height dimensions HX1 and HX2, the semiconductor element 30X may be mounted in an inclined state with respect to the first lead front surface 21S of the first leads 21A to 21C and the second lead front surface 22S of the second leads 22A to 22D.

In this way, when the semiconductor element 30X is mounted in an inclined state with respect to the first lead front surface 21S and the second lead front surface 22S, there is a risk that voids may be generated at a bonding portion between the plurality of first electrode terminals 50X and the first lead front surface 21S. As a result, a connection strength between the plurality of first electrode terminals 50X and the first leads 21A to 21C may decrease, or an electrical resistance between the plurality of first electrode terminals 50X and the first leads 21A to 21C may increase.

In this regard, in the first embodiment, as shown in FIG. 5, an area of each second electrode terminal 60 in a plan view is larger than an area of each first electrode terminal 50 in a plan view. As a result, a current density when performing electrolytic plating to form each second electrode terminal 60 is smaller than the current density when forming the second electrode terminal 60X of the comparative example. In other words, the current density when performing electrolytic plating to form each second electrode terminal 60 approaches the current density when performing electrolytic plating to form each first electrode terminal 50. As a result, a difference HD (HD=H2−H1) between the height dimension H2 of each second electrode terminal 60 and the height dimension H1 of each first electrode terminal 50 of the first embodiment shown in FIG. 6 is smaller than a difference HDX (HDX=HX2−HX1) between the height dimension HX2 of each second electrode terminal 60X and the height dimension HX1 of each first electrode terminal 50X shown in FIG. 11. This prevents the semiconductor element 30 from being mounted in an inclined state with respect to the first lead front surface 21S and the second lead front surface 22S, as shown in FIG. 7. Therefore, this prevents a connection strength between the plurality of first electrode terminals 50 and the first leads 21A to 21C from decreasing or an electrical resistance between the plurality of first electrode terminals 50 and the first leads 21A to 21C from increasing.

### [Effects]

According to the first embodiment, the following effects can be achieved.
(1-1) The semiconductor element 30 includes the element front surface 31, the element back surface 32 facing an opposite side from the element front surface 31, the first electrode 44A and the second electrode 44B formed over the element front surface 31, the plurality of first electrode terminals 50 in contact with the first electrode 44A, the plurality of second electrode terminals 60 in contact with the second electrode 44B, the first region 31A in which the plurality of first electrode terminals 50 are arranged, and the second region 31B in which the plurality of second electrode terminals 60 are arranged. The number of second electrode terminals 60 per unit area in the second region 31B is smaller than the number of first electrode terminals 50 per unit area in the first region 31A. The area of the second electrode terminal 60 is larger than the area of the first electrode terminal 50 in a plan view.

According to the above-described configuration, it is possible to reduce variations in the height dimension H1 of the plurality of first electrode terminals 50 and the height dimension H2 of the plurality of second electrode terminals 60. Therefore, when the semiconductor element 30 is bonded to, for example, the first lead 21 and the second lead 22, a bonding strength between the first electrode terminal 50 and the first lead 21 and a bonding strength between the second electrode terminal 60 and the second lead 22 are suppressed from varying from each other. Therefore, it is possible to reduce variations in the connection states of the plurality of first electrode terminals 50 and the plurality of second electrode terminals 60.
(1-2) The shape of the second electrode terminal 60 in a plan view is rectangular.

According to the above-described configuration, it is easier to increase the area of the second electrode terminal 60 in a plan view than when the second electrode terminal 60 has a circular shape in a plan view.

### Second Embodiment

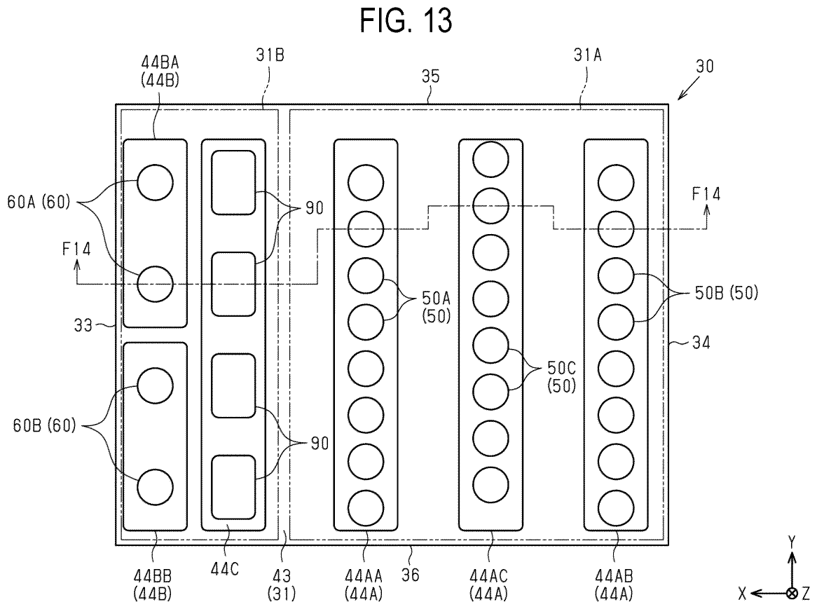

A semiconductor device 10 according to a second embodiment of the present disclosure will be described with reference to FIGS. 13 to 16. The semiconductor device 10 according to the second embodiment is mainly different from the semiconductor device 10 according to the first embodiment in terms of the shape of each second electrode terminal 60 and in that a third electrode 44C and a dummy terminal 90 are provided in the semiconductor element 30. Hereinafter, the same constituent elements as those in the first embodiment are denoted by the same reference numerals, and the explanation thereof may be omitted.

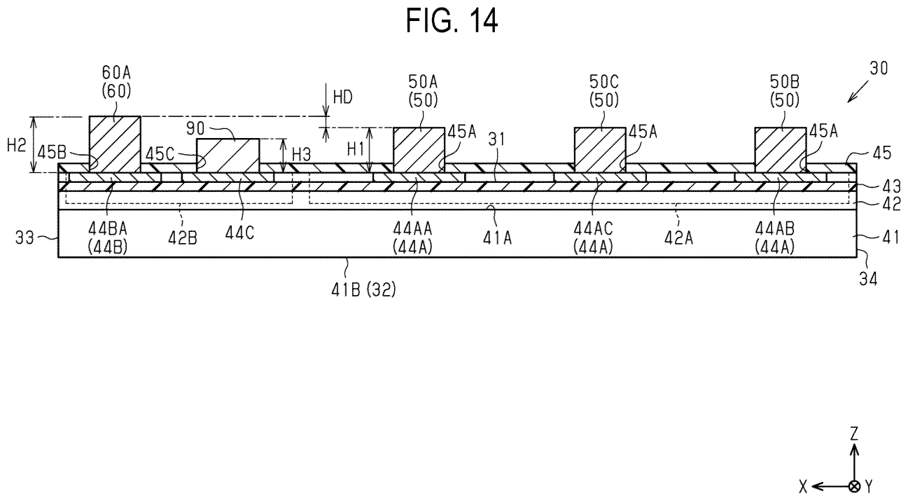

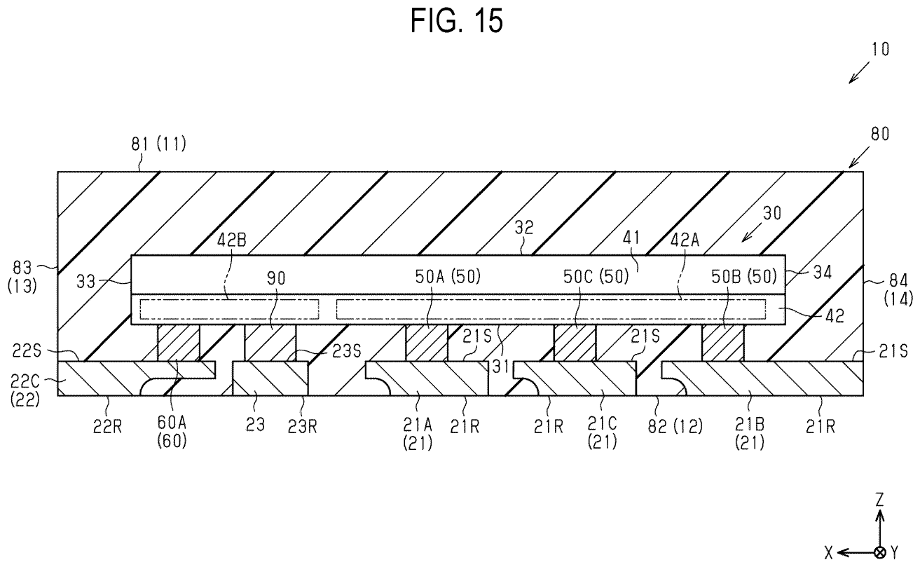

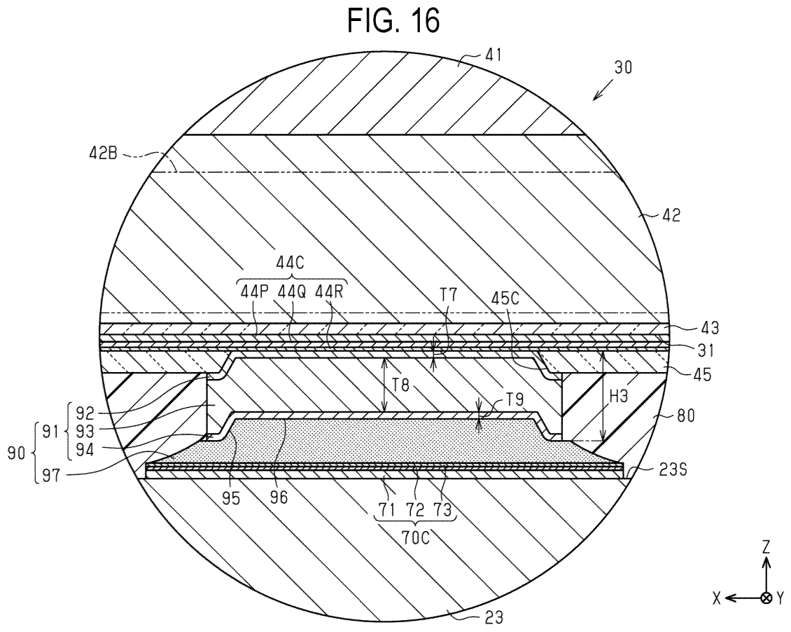

FIG. 13 shows a schematic planar structure of the semiconductor element 30 in the semiconductor device 10 according to the second embodiment. The insulating layer 45 is omitted in FIG. 13. FIG. 14 shows a schematic cross-sectional structure of the semiconductor element 30 taken along line F14-F14 in FIG. 13. FIG. 15 shows a schematic cross-sectional structure of the semiconductor device 10 taken along the XZ plane. FIG. 16 shows an enlarged schematic cross-sectional structure of the dummy terminal 90 and its surroundings in FIG. 15.

As shown in FIG. 13, each second electrode terminal 60 is formed in a circular shape in a plan view. That is, in the second embodiment, the shape of each second electrode terminal 60 in a plan view is the same as the shape of each first electrode terminal 50 in a plan view. Further, in an example, an area of each second electrode terminal 60 in a plan view is equal to an area of each first electrode terminal 50 in a plan view. Here, in a case where a difference between the area of each second electrode terminal 60 in a plan view and the area of each first electrode terminal 50 in a plan view is, for example, within 10% of the area of each second electrode terminal 60 in a plan view, it can be said that the area of each second electrode terminal 60 in a plan view is equal to the area of each first electrode terminal 50 in a plan view. In the second embodiment, a distance between second electrode terminals 60 adjacent to each other in the Y direction on the second electrode 44B is larger than that in the first embodiment.

The semiconductor element 30 further includes the third electrode 44C formed in the second region 31B of the element front surface 31. The third electrode 44C is provided near the second electrode 44B between the first electrode 44AA corresponding to the first lead 21A and the second electrode 44B in the X direction. The third electrode 44C is formed in a strip shape extending in the Y direction in a plan view. In an example, a dimension of the third electrode 44C in the Y direction is equal to a dimension of the first electrode 44A in the Y direction. The dimension and the shape of the third electrode 44C in the Y direction may be changed arbitrarily. In an example, the dimension of the third electrode 44C in the Y direction may be larger than the dimension of the first electrode 44A in the Y direction.

As shown in FIG. 14, the third electrode 44C is arranged at the same position as the first electrode 44A and the second electrode 44B in the Z direction. Therefore, the third electrode 44C is covered with the insulating layer 45. On the other hand, a third opening 45C is formed in the insulating layer 45 to expose a portion of the third electrode 44C. The third electrode 44C is insulated from the first electrode 44A and the second electrode 44B. In an example, the third electrode 44C is in an electrically floating state. The configuration of the third electrode 44C is, for example, the same as that of the first electrode 44A. Therefore, the same constituent elements of the third electrode 44C as the first electrode 44A are denoted by the same reference numerals, and the explanation thereof will be omitted.

At least one dummy terminal 90 is provided over the third electrode 44C exposed from the insulating layer 45. In an example, a plurality of dummy terminals 90 (four dummy terminals 90 in the second embodiment) are provided. The plurality of dummy terminals 90 are arranged at the same position in the X direction and spaced apart from each other in the Y direction. Each dummy terminal 90 is in contact with the third electrode 44C exposed through the third opening 45C.

As shown in FIG. 13, the shapes of the dummy terminals 90 are the same in a plan view. On the other hand, in a plan view, the shape of each dummy terminal 90 is different from the shape of each first electrode terminal 50. In a plan view, the shape of each dummy terminal 90 is different from the shape of each second electrode terminal 60. In the example shown in FIG. 13, each dummy terminal 90 is formed in a rectangular shape in a plan view. In an example, each dummy terminal 90 is formed in a rectangular shape with the Y direction being a longitudinal direction and the X direction being a lateral direction.

In a plan view, the area of each dummy terminal 90 is larger than the area of each first electrode terminal 50. In a plan view, the area of each dummy terminal 90 is larger than the area of each second electrode terminal 60. Here, the area of the dummy terminal 90 in a plan view can be defined by an area of a tip surface 96 (see FIG. 16) of a third pillar portion 91 of the dummy terminal 90 in a plan view.

In the second embodiment, the shape of each first electrode terminal 50, the shape of each second electrode terminal 60, and the shape of each dummy terminal 90 in a plan view may be changed arbitrarily. In an example, the shape of each first electrode terminal 50 and each second electrode terminal 60 in a plan view may be any one of an elliptical shape, an oval shape, a rectangular shape, and a polygonal shape. In an example, the shape of each dummy terminal 90 in a plan view may be any one of a circular shape, an elliptical shape, an oval shape, and a polygonal shape. Further, for example, in a plan view, the shape of each dummy terminal 90 may be the same as the shape of each first electrode terminal 50 or each second electrode terminal 60.

As shown in FIG. 14, a height dimension H3 of each dummy terminal 90 is lower than the height dimension H2 of each second electrode terminal 60. Further, the height dimension H3 of each dummy terminal 90 is slightly lower than the height dimension H1 of each first electrode terminal 50. Here, the height dimension H3 of the dummy terminal 90 can be defined by a maximum distance between the third electrode 44C and the tip surface 96 of the third pillar portion 91 of the dummy terminal 90 in the Z direction.

The difference HD (HD=H2−H1) between the height dimension H1 of each first electrode terminal 50 and the height dimension H2 of each second electrode terminal 60 is smaller than the difference HDX (HDX=HX2−HX1) between the height dimension HX2 of each second electrode terminal 60X and the height dimension HX1 of each first electrode terminal 50X shown in FIG. 11.

Here, the height dimension H2 of each second electrode terminal 60 is changed according to the area of each dummy terminal 90 in a plan view. That is, the height dimension H2 of each second electrode terminal 60 becomes smaller as the area of each dummy terminal 90 in a plan view becomes larger. Therefore, by adjusting the area of each dummy terminal 90 in a plan view, the height dimension H2 of each second electrode terminal 60 may be equal to or slightly smaller than the height dimension H1 of each first electrode terminal 50.

As shown in FIG. 15, the semiconductor device 10 includes a third lead 23 arranged to face the dummy terminal 90 in the Z direction. A plurality of third leads 23 may be provided according to the number of dummy terminals 90, for example. The third lead 23 is arranged to be spaced apart from both the first lead 21 and the second lead 22. That is, the third lead 23 is insulated from both the first lead 21 and the second lead 22. The number of third leads 23 may be changed arbitrarily. In an example, a common third lead 23 may be provided for a plurality of third leads 23.

The third lead 23 has a third lead front surface 23S and a third lead back surface 23R facing opposite sides from each other in the Z direction. The third lead front surface 23S faces the same side as the first lead front surface 21S, and the third lead back surface 23R faces the same side as the first lead back surface 21R. The semiconductor element 30 is supported by the second lead front surface 22S of the third lead 23. The third lead back surface 23R is exposed from the sealing back surface 82 of the sealing resin 80.

As shown in FIG. 16, a connection structure between the dummy terminal 90 and the second lead 22 is the same as the connection structure between the second electrode terminal 60 and the second lead 22, for example. That is, each dummy terminal 90 includes a third pillar portion 91 and a third solder portion 97. The third pillar portion 91 includes a third seed layer 92, a third plating layer 93, and a third front surface side plating layer 94. The third solder portion 97 is formed over the third front surface side plating layer 94. A third recess 95 is provided in the third pillar portion 91. The third solder portion 97 is provided over the tip surface 96 of the third pillar portion 91. Further, each dummy terminal 90 is manufactured, for example, in the same steps as the first electrode terminal 50 and the second electrode terminal 60.

The third solder portion 97 of the dummy terminal 90 electrically connects the third pillar portion 91 and the third lead 23 by being interposed between the third pillar portion 91 and the third lead 23. A third plating layer 70C is interposed between the third solder portion 97 and the third lead front surface 23S of the third lead 23 in the Z direction. The third plating layer 70C electrically connects the third solder portion 97 and the third lead 23. The third plating layer 70C functions to suppress a chemical combination reaction between the third lead 23 and the third solder portion 97. The material of the third plating layer 70C is not particularly limited, and any metal material that can suppress the chemical combination reaction may be selected as appropriate. Examples of the metal material may include Ni, Fe, and the like. In the example shown in FIG. 16, the third plating layer 70C is provided so as to partially cover the third lead front surface 23S. The configuration of the third plating layer 70C is the same as the configuration of the first plating layer 70A. Therefore, the same constituent elements in the third plating layer 70C as in the first plating layer 70A are denoted by the same reference numerals, and the explanation thereof will be omitted.

As shown in FIGS. 8, 9, and 16, a thickness T7 of the third seed layer 92 of the third pillar portion 91 of the dummy terminal 90 is equal to, for example, the thickness T2 of the seed layer 62 of the second pillar portion 61 of the second electrode terminal 60. Here, in a case where a difference between the thickness T7 and the thickness T2 is, for example, within 10% of the thickness T7, it can be said that the thickness T7 of the third seed layer 92 is equal to the thickness T2 of the second seed layer 62. A thickness T8 of the third plating layer 93 of the third pillar portion 91 of the dummy terminal 90 is slightly thinner than, for example, the thickness T3 of the first plating layer 53 of the first pillar portion 51 of the first electrode terminal 50. Further, a thickness T9 of the third front surface side plating layer 94 of the dummy terminal 90 is equal to, for example, the thickness T6 of the second front surface side plating layer 64 of the second electrode terminal 60. Here, in a case where a difference between the thickness T9 and the thickness T6 is, for example, within 10% of the thickness T9, it can be said that the thickness T9 of the third front surface side plating layer 94 is equal to the thickness T6 of the second front surface side plating layer 64. In this way, based on the fact that the thickness T8 of the third plating layer 93 is slightly thinner than the thickness T3 of the first plating layer 53, the height dimension H3 of each dummy terminal 90 becomes lower than the height dimension H1 of each first electrode terminal 50. Further, the thickness T8 of the third plating layer 93 is thinner than, for example, the thickness T5 of the second plating layer 63 of the second pillar portion 61 of the second electrode terminal 60. As a result, the height dimension H3 of each dummy terminal 90 becomes lower than the height dimension H2 of each second electrode terminal 60.

### [Effects]

According to the second embodiment of the present disclosure, the following effects can be achieved.
(2-1) The semiconductor element 30 includes the element front surface 31, the element back surface 32 facing the opposite side from the element front surface 31, the first electrode 44A and the second electrode 44B formed over the element front surface 31, the plurality of first electrode terminals 50 in contact with the first electrode 44A, the plurality of second electrode terminals 60 in contact with the second electrode 44B, the first region 31A in which the plurality of first electrode terminals 50 are arranged, and the second region 31B in which the plurality of second electrode terminals 60 are arranged. The number of second electrode terminals 60 per unit area in the second region 31B is smaller than the number of first electrode terminals 50 per unit area in the first region 31A. The dummy terminal 90 is provided in the second region 31B.

According to the above-described configuration, the current density when performing electrolytic plating to form each second electrode terminal 60 is lower than that in a case where the dummy terminal 90 is not provided. In other words, the current density when performing electrolytic plating to form each second electrode terminal 60 approaches the current density when performing electrolytic plating to form each first electrode terminal 50. As a result, it is possible to reduce variations in the height dimension H1 of the plurality of first electrode terminals 50 and the height dimension H2 of the plurality of second electrode terminals 60. Therefore, when the semiconductor element 30 is bonded to, for example, the first lead 21 and the second lead 22, the bonding strength between the first electrode terminal 50 and the first lead 21 and the bonding strength between the second electrode terminal 60 and the second lead 22 are suppressed from varying from each other. Therefore, it is possible to reduce variations in the connection states between the plurality of first electrode terminals 50 and the plurality of second electrode terminals 60.
(2-2) The dummy terminal 90 is arranged to be closer to the second electrode terminal 60 than the first electrode terminal 50. According to this configuration, it is easy to decrease the current density when performing electrolytic plating to form each second electrode terminal 60.
(2-3) The semiconductor element 30 further includes the third electrode 44C formed in the second region 31B of the element front surface 31. The third electrode 44C is provided near the second electrode 44B between the first electrode 44A and the second electrode 44B in the X direction. The dummy terminal 90 is in contact with the third electrode 44C.

According to above-described configuration, it is possible to manufacture the dummy terminal 90 in the same process as the first electrode terminal 50 and the second electrode terminal 60. Therefore, it is possible to simplify the manufacturing process of the semiconductor element 30.
(2-4) The height dimension H3 of the dummy terminal 90 is smaller than the height dimension H2 of the second electrode terminal 60. According to this configuration, due to the fact that the height dimension H3 of the dummy terminal 90 is larger than the height dimension H2 of the second electrode terminal 60, it is possible to suppress variations in the connection state between the second electrode terminal 60 and the first electrode terminal 50.
(2-5) The shape of the dummy terminal 90 in a plan view is rectangular. According to this configuration, it is easier to increase the area of the dummy terminal 90 in a plan view than when the dummy terminal 90 has a circular shape in a plan view.

### Third Embodiment

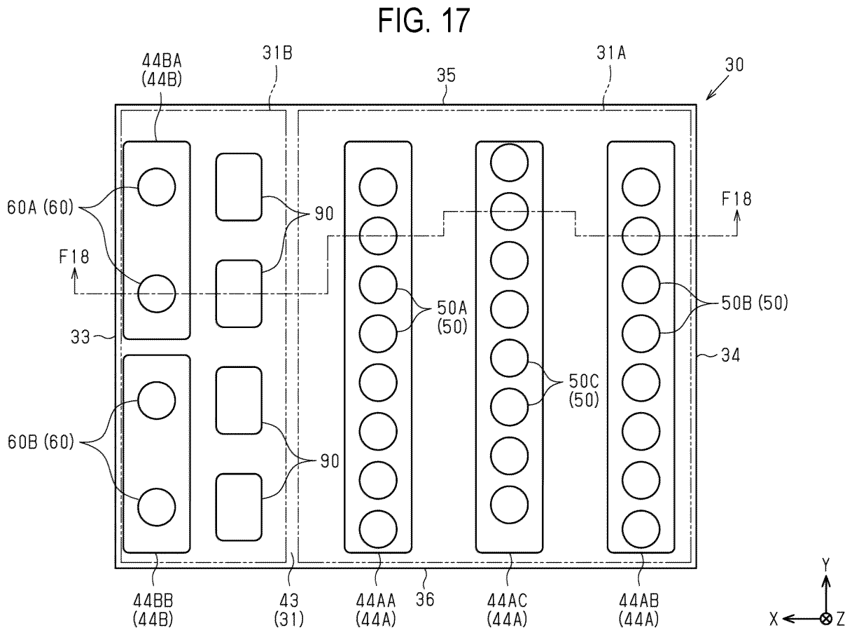

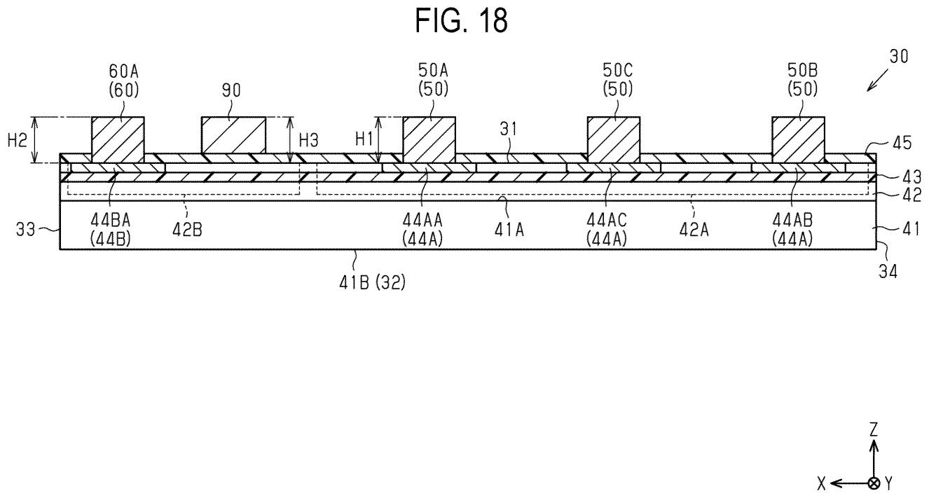

A semiconductor device 10 according to a third embodiment of the present disclosure will be described with reference to FIGS. 17 and 18. The semiconductor device 10 according to the third embodiment is mainly different from the semiconductor device 10 according to the second embodiment in that the third electrode 44C is omitted. Hereinafter, the same constituent elements as the second embodiment are denoted by the same reference numerals, and the explanation thereof may be omitted.

As shown in FIG. 17, the semiconductor device 10 of the third embodiment does not include the third electrode 44C (see FIG. 13). That is, each dummy terminal 90 is provided over the insulating layer 45. Each dummy terminal 90 is in an electrically floating state.

As shown in FIG. 18, the height dimension H3 of each dummy terminal 90 is equal to the height dimension H2 of each second electrode terminal 60. The height dimension H3 of each dummy terminal 90 is equal to the height dimension H1 of each first electrode terminal 50. Therefore, the height dimension H2 of each second electrode terminal 60 is equal to the height dimension H1 of each first electrode terminal 50. Here, the height dimension H3 of the dummy terminal 90 can be defined, for example, by the maximum distance between the surface of the second electrode 44B and the tip surface 96 of the third pillar portion 91 of the dummy terminal 90 in the Z direction. Further, in a case where a difference between the height dimension H3 and the height dimension H2 is, for example, within 10% of the height dimension H3, it can be said that the height dimension H3 of each dummy terminal 90 is equal to the height dimension H2 of each second electrode terminal 60. In a case where a difference between the height dimension H3 and the height dimension H1 is, for example, within 10% of the height dimension H3, it can be said that the height dimension H3 of each dummy terminal 90 is equal to the height dimension H1 of each first electrode terminal 50. In other words, when the height dimension H3 of each dummy terminal 90 is equal to the height dimension H2 of each second electrode terminal 60, it means that the position of the tip surface 96 of each dummy terminal 90 is the same as a position of the tip surface 66 of each second electrode terminal 60 in the Z direction. Further, when the height dimension H3 of each dummy terminal 90 is equal to the height dimension H1 of each first electrode terminal 50, it means that the position of the tip surface 96 of each dummy terminal 90 is the same as a position of the tip surface 56 of each first electrode terminal 50 in the Z direction. According to the third embodiment, effects similar to (2-1), (2-2), and (2-5) in the second embodiment can be obtained.

### Modifications

Each of the above-described embodiments can be modified and implemented as follows. Moreover, each of the above-described embodiments and each of the following modifications can be implemented in combination with one another unless technically contradictory.

-In the second and third embodiments, the number of dummy terminals 90 may be changed arbitrarily. In an example, the number of dummy terminals 90 may be one. Further, in an example, the number of dummy terminals 90 may be five or more.

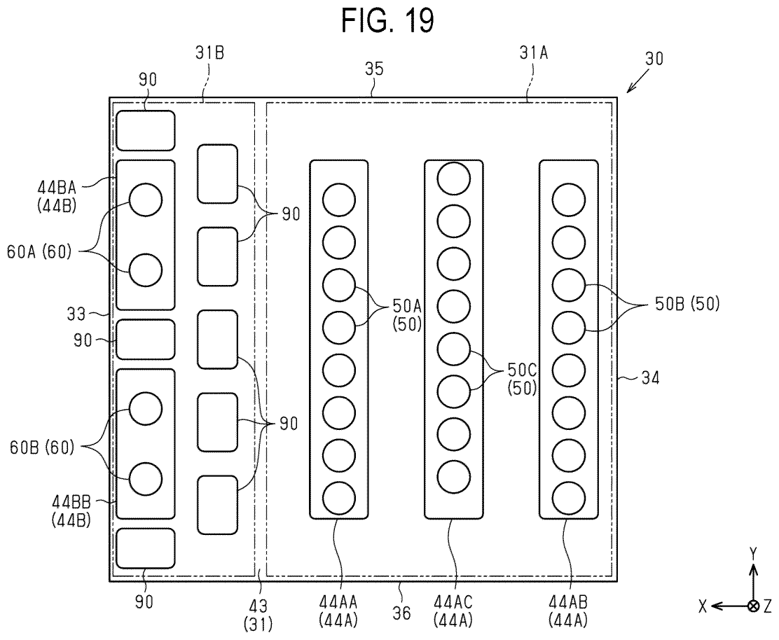

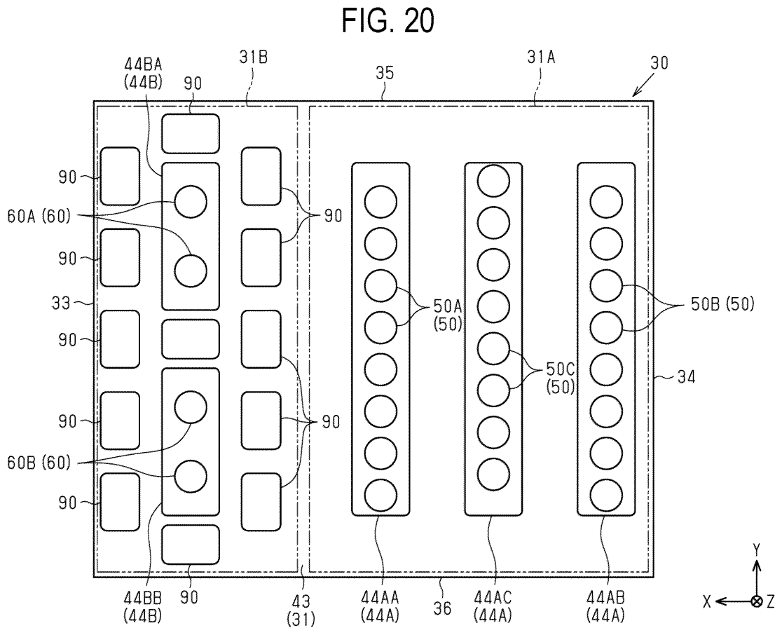

-In the third embodiment, the number and an arrangement aspect of dummy terminals 90 may be changed arbitrarily. For example, examples of the arrangement aspect of the plurality of dummy terminals 90 may include a first modification shown in FIG. 19 and a second modification shown in FIG. 20.

As shown in FIG. 19, in the first modification, a plurality of dummy terminals 90 may be arranged so as to surround a plurality of second electrode terminals 60A and a plurality of second electrode terminals 60B from three sides in a plan view. More specifically, the plurality of dummy terminals 90 include dummy terminals 90 arranged at positions overlapping the plurality of second electrode terminals 60A and closer to the sealing side surface 85 than the plurality of second electrode terminals 60A when viewed from the Y direction. The plurality of dummy terminals 90 include dummy terminals 90 arranged at positions overlapping the plurality of second electrode terminals 60B and closer to the sealing side surface 86 than the plurality of second electrode terminals 60B when viewed from the Y direction. The plurality of dummy terminals 90 include dummy terminals 90 arranged at positions overlapping the plurality of second electrode terminals 60A and 60B and located between the plurality of second electrode terminals 60A and the plurality of second electrode terminals 60B in the Y direction when viewed from the Y direction.

As shown in FIG. 20, in the second modification, a plurality of dummy terminals 90 may be arranged so as to individually surround a plurality of second electrode terminals 60A and a plurality of second electrode terminals 60B in a plan view. That is, the plurality of dummy terminals 90 include a plurality of dummy terminals 90 arranged so as to surround the plurality of second electrode terminals 60A in a plan view. The plurality of dummy terminals 90 include a plurality of dummy terminals 90 arranged so as to surround the plurality of second electrode terminals 60B in a plan view. In this case, the second electrode 44B and the plurality of second electrode terminals 60A and 60B are arranged at positions separated from the sealing side surface 84 in the X direction. That is, a plurality of dummy terminals 90 are arranged between the second electrode 44B and the sealing side surface 84 in the X direction. In other words, the second electrode 44B is arranged to be spaced apart from the sealing side surface 84 in the X direction by a region where the plurality of dummy terminals 90 are arranged.

The first modification shown in FIG. 19 and the second modification shown in FIG. 20 can be similarly applied to the second embodiment. In this case, the semiconductor device 10 includes the third electrodes 44C that individually surround the plurality of second electrodes 44B in a plan view. Further, in the first modification and the second modification, the dummy terminals 90 arranged at positions overlapping the plurality of second electrode terminals 60A and 60B and located between the plurality of second electrode terminals 60A and the plurality of second electrode terminals 60B in the Y direction when viewed from the Y direction may be omitted.

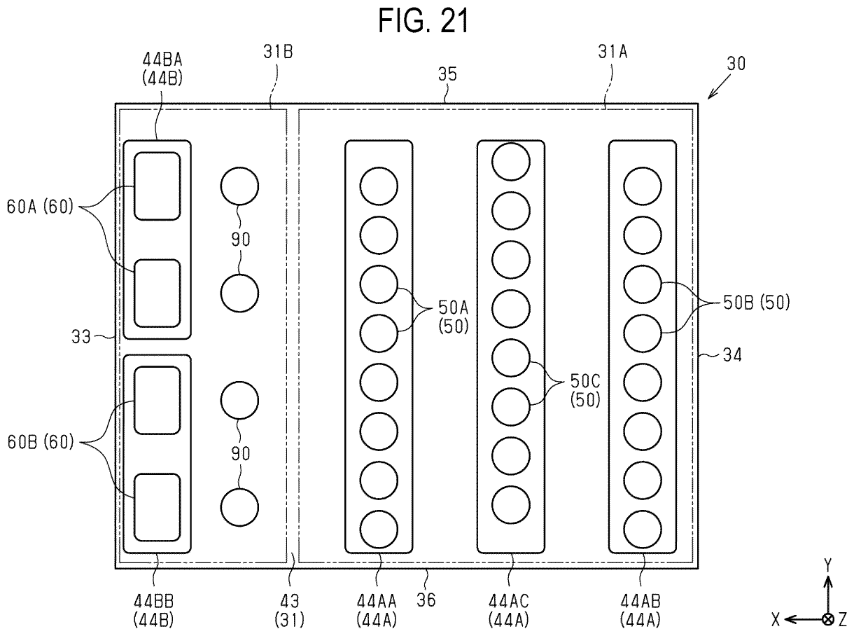

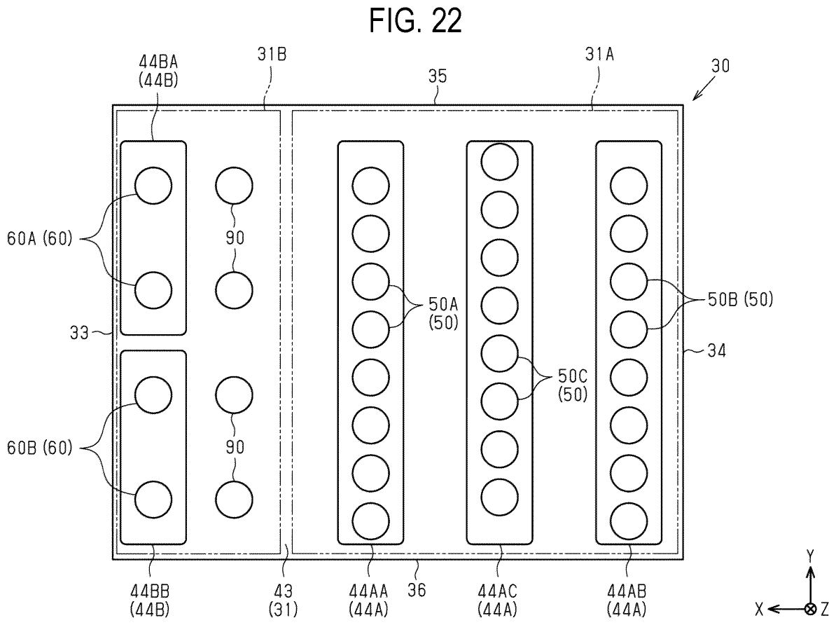

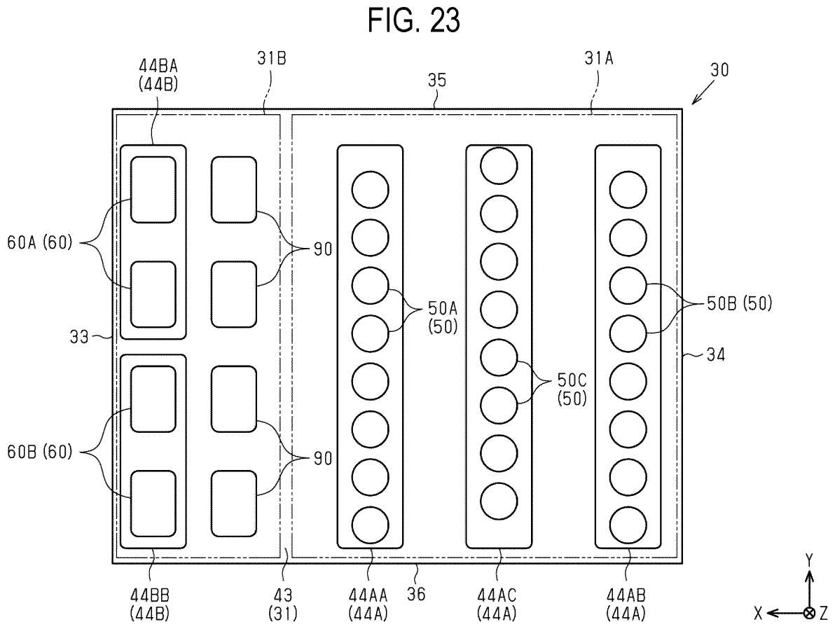

-In the third embodiment, the combinations of shapes of each dummy terminal 90 and each second electrode terminal 60 in a plan view may be changed arbitrarily. Examples of the combinations of shapes of each dummy terminal 90 and each second electrode terminal 60 in a plan view may include a first modification shown in FIG. 21, a second modification shown in FIG. 22, and a third modification shown in FIG. 23.

As shown in FIG. 21, in the first modification, the shape of the second electrode terminal 60 in a plan view is rectangular, and the shape of the dummy terminal 90 in a plan view is circular. In the example shown in FIG. 21, the second electrode terminal 60 in a plan view has a rectangular shape with the Y direction being a longitudinal direction and the X direction being a lateral direction. In this case, the area of the second electrode terminal 60 in a plan view is larger than the area of the dummy terminal 90 in a plan view.

As shown in FIG. 22, in the second modification, the shape of the second electrode terminal 60 in a plan view is circular, and the shape of the dummy terminal 90 in a plan view is circular. That is, the shape of the second electrode terminal 60 in a plan view and the shape of the dummy terminal 90 in a plan view may be the same. In an example, the area of the second electrode terminal 60 in a plan view is equal to the area of the dummy terminal 90 in a plan view.

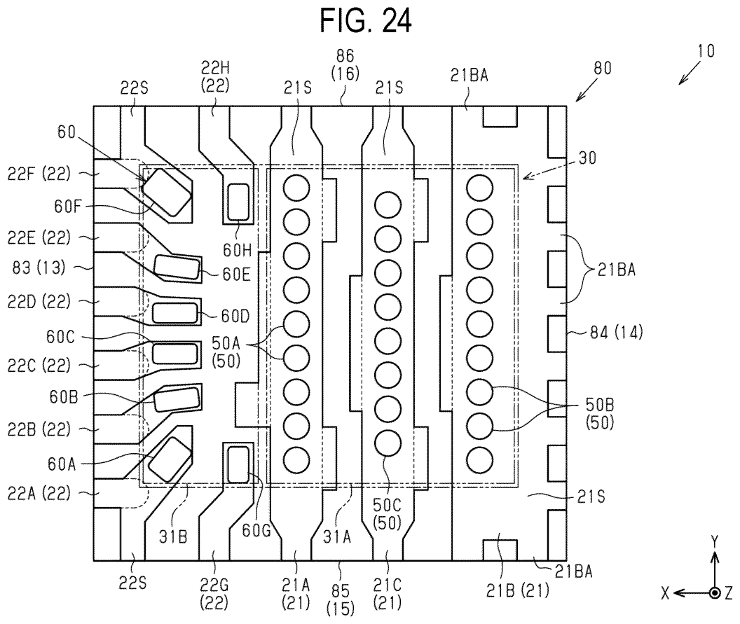

As shown in FIG. 23, in the third modification, the shape of the second electrode terminal 60 in a plan view is rectangular, and the shape of the dummy terminal 90 in a plan view is rectangular. That is, the shape of the second electrode terminal 60 in a plan view and the shape of the dummy terminal 90 in a plan view may be the same. In an example, the area of the second electrode terminal 60 in a plan view is equal to the area of the dummy terminal 90 in a plan view. Further, the area of the dummy terminal 90 in a plan view is larger than the area of the first electrode terminal 50 in a plan view. The area of the second electrode terminal 60 in a plan view is larger than the area of the first electrode terminal 50 in a plan view.
In the third embodiment, the dummy terminal 90 is provided over the insulating layer 45, but the present disclosure is not limited thereto. The dummy terminal 90 may be provided, for example, on the element front surface 31 of the semiconductor element 30.
In each embodiment, the number and arrangement aspects of the second leads 22 may be changed arbitrarily. In an example, as shown in FIG. 24, the semiconductor device 10 includes second leads 22A to 22H. The second leads 22A to 22H are arranged to be closer to the sealing side surface 83 than the first leads 21A to 21C. The second leads 22A to 22F are arranged to be spaced apart from each other in the Y direction, for example. The second leads 22A, 22B, 22C, 22D, 22E, and 22F are arranged in this order from the sealing side surface 85 toward the sealing side surface 86. The second lead 22G is arranged between the second lead 22A and the first lead 21A in the X direction. The second lead 22H is arranged between the second lead 22F and the first lead 21A in the X direction.

The number and arrangement aspect of the second electrode terminals 60 are changed as appropriate according to the number and arrangement aspect of the second leads 22. Although not shown, the second electrode 44B may be changed as appropriate according to the number and arrangement aspect of the second electrode terminals 60.

The semiconductor element 30 includes second electrode terminals 60A to 60H as a plurality of second electrode terminals 60. In the example shown in FIG. 24, the second electrode terminals 60A to 60H are formed in a rectangular shape in a plan view. The second electrode terminals 60A to 60H in a plan view include those having different shapes and sizes. The shape and size of the second electrode terminals 60A to 60H in a plan view are changed as appropriate according to the shape and size of the second leads 22A to 22H facing the second region 31B of the semiconductor element 30.

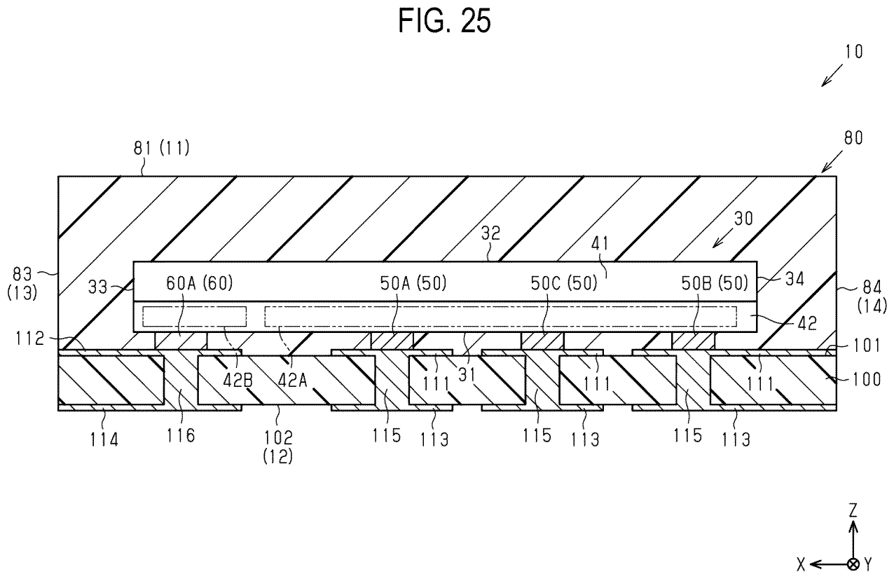

In the example shown in FIG. 24, a ratio of the area of the second region 31B to the area of the first region 31A is smaller than a ratio of the number of second electrode terminals 60 to the number of first electrode terminals 50. Therefore, the number of second electrode terminals 60 per unit area in the second region 31B is smaller than the number of first electrode terminals 50 per unit area in the first region 31A. The area of each of the second electrode terminals 60A to 60H in a plan view is larger than the area of the first electrode terminal 50 in a plan view.
In each embodiment, the configuration of the second electrode 44B may be changed arbitrarily. In an example, the number of second electrodes 44B may be set according to the number of second electrode terminals 60. In a case where the number of second electrode terminals 60 is four, four second electrodes 44B may be provided to be spaced apart from one another. The four second electrode terminals 60 may be individually connected electrically to the four second electrodes 44B. In other words, the semiconductor device 10 may include a plurality of second electrode terminals 60 that are individually connected electrically to a plurality of second electrodes 44B.
In each embodiment, the configuration for supporting the semiconductor element 30 may be changed arbitrarily. In an example, as shown in FIG. 25, the semiconductor device 10 includes a substrate 100 instead of the first leads 21A to 21C and the second leads 22A to 22D.

The substrate 100 is formed in a rectangular flat plate shape with the Z direction as a thickness direction. The substrate 100 has a substrate front surface 101 and a substrate back surface 102 facing opposite sides from each other in the Z direction. The substrate front surface 101 faces the same side as the device front surface 11, and the substrate back surface 102 faces the same side as the device back surface 12. The substrate back surface 102 constitutes the device back surface 12. The substrate 100 is formed of an insulating material. Epoxy resin is used as an example of the insulating material.

The semiconductor device 10 includes a plurality of first front surface wirings 111 and a plurality of second front surface wirings 112 formed over the substrate front surface 101. Each first front surface wiring 111 and each second front surface wiring 112 are made of a metal layer formed over the substrate front surface 101. The metal layer contains at least one selected from the group of, for example, Cu, Al, Ag, Au, Ni, and Ti.

A plurality of first electrode terminals 50 of the semiconductor element 30 are individually connected electrically to the plurality of first front surface wirings 111. The plurality of first front surface wirings 111 are provided corresponding to the first electrode terminals 50A to 50C (see FIG. 2). That is, the plurality of first front surface wirings 111 include a first front surface wiring 111 corresponding to the first electrode terminal 50A, a first front surface wiring 111 corresponding to the first electrode terminal 50B, and a first front surface wiring 111 corresponding to the first electrode terminal 50C.

A plurality of second electrode terminals 60 are individually connected electrically to the plurality of second front surface wirings 112. The plurality of second front surface wirings 112 are provided corresponding to the second electrode terminals 60A to 60D (see FIG. 2). That is, the plurality of second front surface wirings 112 include a second front surface wiring 112 corresponding to the second electrode terminal 60A, a second front surface wiring 112 corresponding to the second electrode terminal 60B, a second front surface wiring 112 corresponding to the second electrode terminal 60C, and a second front surface wiring 112 corresponding to the second electrode terminal 60D. The configuration and arrangement aspect of each first electrode terminal 50 and each second electrode terminal 60 are, for example, the same as those in the first embodiment.

The semiconductor device 10 includes a plurality of first back surface wirings 113 and a plurality of second back surface wirings 114 formed over the substrate back surface 102, and a plurality of first through-wirings 115 and a plurality of second through-wirings 116 which penetrate the substrate 100 in the Z direction.

The plurality of first back surface wirings 113 are electrically connected to the plurality of first front surface wirings 111 via the plurality of first through-wirings 115. Therefore, the plurality of first back surface wirings 113 are individually connected electrically to the first electrode terminals 50A to 50C.

The plurality of second back surface wirings 114 are electrically connected to the plurality of second front surface wirings 112 via the plurality of second through-wirings 116. Therefore, the plurality of second back surface wirings 114 are individually connected electrically to the second electrode terminals 60A to 60D.

The sealing resin 80 is provided over the substrate front surface 101 of the substrate 100. The sealing resin 80 seals the semiconductor element 30, the plurality of first front surface wirings 111, and the plurality of second front surface wirings 112. According to the semiconductor device 10 shown in FIG. 25, the same effects as the first embodiment can be obtained. The semiconductor elements 30 of the second and third embodiments may also be applied to a modification shown in FIG. 25. Further, in the modification shown in FIG. 25, the sealing resin 80 may be omitted from the semiconductor device 10.

One or more of the various examples described in the present disclosure may be combined unless technically contradictory. The terms such as “first,” “second,” and “third” in the present disclosure are used merely to distinguish objects from one another and are not intended to prioritize the objects.

In the present disclosure, “at least one selected from the group of A and B” should be understood to mean “only A, only B, or both A and B.” The term “on” as used in the present disclosure includes the meanings of “on” and “above” unless clearly stated otherwise in the context. Therefore, for example, the expression “a first element is arranged on a second element” is intended that in some embodiments, the first element can be directly arranged on the second element in contact with the second element, while in other embodiments, the first element can be arranged above the second element without contacting the second element. That is, the term “on” does not exclude a structure in which other elements are formed between the first element and the second element.

The Z direction used in the present disclosure does not necessarily have to be a vertical direction, and it does not have to be exactly the same as the vertical direction. Therefore, various structures according to the present disclosure are not limited to “up” and “down” in the Z direction described herein being “up” and “down” in the vertical direction. For example, the X direction may be the vertical direction, or the Y direction may be the vertical direction.

### SUPPLEMENTARY NOTES

The technical features which can be understood from the present disclosure are described below. For the purpose of aiding understanding and not for the purpose of limitation, constituent elements described in supplementary notes are labeled with the reference numerals of the corresponding constituent elements in the above-described embodiments. The reference numerals are provided as examples to aid understanding, and the constituent elements described in supplementary notes should not be limited to the constituent elements indicated by the reference numerals.

### Supplementary Note 1

A semiconductor element (30) including:
an element front surface (31) and an element back surface (32) facing an opposite side from the element front surface (31);
a first electrode (44A) and a second electrode (44B) that are formed over the element front surface (31);
a plurality of first electrode terminals (50) in contact with the first electrode (44A);
a plurality of second electrode terminals (60) in contact with the second electrode (44B);
a first region (31A) in which the plurality of first electrode terminals (50) are arranged; and
a second region (31B) in which the plurality of second electrode terminals (60) are arranged,
wherein the number of the second electrode terminals (60) per unit area in the second region (31B) is smaller than the number of the first electrode terminals (50) per unit area in the first region (31A), and
wherein an area of each of the second electrode terminals (60) is larger than an area of each of the plurality of first electrode terminals (50) when viewed from a thickness direction (Z direction) which is perpendicular to the element front surface (31).

### Supplementary Note 2

The semiconductor element of Supplementary Note 1, wherein the first region (31A) is a region in which a first transistor and a second transistor connected in series with each other are formed,
wherein the second region (31B) is a region in which a control circuit configured to control the first transistor and the second transistor is formed,
wherein the plurality of first electrode terminals (50) are electrically connected to the first transistor and the second transistor, and
wherein the plurality of second electrode terminals (60) are electrically connected to the control circuit.

### Supplementary Note 3

The semiconductor element of Supplementary Note 1 or 2, wherein a shape of each of the second electrode terminals (60) viewed from the thickness direction (Z direction) is different from a shape of each of the first electrode terminals (50) viewed from the thickness direction (Z direction), and
wherein the shape of each of the first electrode terminals (50) viewed from the thickness direction (Z direction) is circular.

### Supplementary Note 4

The semiconductor element of Supplementary Note 3, wherein the shape of each of the second electrode terminals (60) viewed from the thickness direction (Z direction) is rectangular.

### Supplementary Note 5

The semiconductor element of any one of Supplementary Notes 1 to 4, wherein each of the first electrode terminals (50) includes a first seed layer (52) in contact with the first electrode (44A), and a first plating layer (53) laminated on the first seed layer (52), and
wherein each of the second electrode terminals (60) includes a second seed layer (62) in contact with the second electrode (44B), and a second plating layer (63) laminated on the second seed layer (62).

### Supplementary Note 6

The semiconductor element of Supplementary Note 5, wherein a thickness (T1) of the first seed layer (52) and a thickness (T2) of the second seed layer (62) are equal to each other.

### Supplementary Note 7

A semiconductor element (30) including:
an element front surface (31) and an element back surface (32) facing an opposite side from the element front surface (31);
a first electrode (44A) and a second electrode (44B) that are formed over the element front surface (31);
a plurality of first electrode terminals (50) in contact with the first electrode (44A);
a plurality of second electrode terminals (60) in contact with the second electrode (44B);
a first region (31A) in which the plurality of first electrode terminals (50) are arranged; and
a second region (31B) in which the plurality of second electrode terminals (60) are arranged,
wherein the number of the second electrode terminals (60) per unit area in the second region (31B) is smaller than the number of the first electrode terminals (50) per unit area in the first region (31A), and
wherein at least one dummy terminal (90) is provided in the second region (31B).

### Supplementary Note 8

The semiconductor element of Supplementary Note 7, wherein the at least one dummy terminal (90) is arranged to be closer to the second electrode terminals (60) than the first electrode terminals (50).

### Supplementary Note 9

The semiconductor element of Supplementary Note 7 or 8, wherein the second electrode terminals (60) are arranged to be spaced apart from the first electrode terminals (50) in a first direction (X direction), when viewed from a thickness direction (Z direction) of the semiconductor element (30),
wherein the semiconductor element further includes a third electrode (44C) formed in the second region (31B) of the element front surface (31),
wherein the third electrode (44C) is provided near the second electrode (44B) between the first electrode (44A) and the second electrode (44B) in the first direction (X direction), and
wherein the at least one dummy terminal (90) is in contact with the third electrode (44C).

### Supplementary Note 10

The semiconductor element of any one of Supplementary Notes 7 to 9, wherein a height dimension (H3) of the at least one dummy terminal (90) is smaller than a height dimension (H2) of each of the second electrode terminals (60).

### Supplementary Note 11

The semiconductor element of any one of Supplementary Notes 7 to 10, wherein a height dimension (H3) of the at least one dummy terminal (90) is smaller than a height dimension (H1) of each of the first electrode terminals (50).

### Supplementary Note 12

The semiconductor element of Supplementary Note 7 or 8, wherein an insulating layer (45) having a first opening (45A) and a second opening (45B) is formed in the element front surface (31),
wherein the first electrode terminals (50) are electrically connected to the first electrode (44A) at the first opening (45A),
wherein the second electrode terminals (60) are electrically connected to the second electrode (44B) at the second opening (45B),
wherein the at least one dummy terminal (90) is provided over the insulating layer (45), and
wherein an area of the at least one dummy terminal (90) viewed from a thickness direction (Z direction) of the semiconductor element (30) is larger than an area of each of the first electrode terminals (50) viewed from the thickness direction (Z direction).

### Supplementary Note 13

The semiconductor element of Supplementary Note 12, wherein a height dimension (H3) of the at least one dummy terminal (90) is equal to a height dimension (H2) of each of the second electrode terminals (60).

### Supplementary Note 14

The semiconductor element of any one of Supplementary Notes 7 to 13, wherein the second electrode terminals (60) are arranged to be spaced apart from the first electrode terminals (50) in a first direction (X direction), when viewed from a thickness direction (Z direction) of the semiconductor element (30),
wherein the plurality of second electrode terminals (60) are arranged to be spaced apart from one another in a second direction (Y direction) perpendicular to the first direction (X direction), when viewed from the thickness direction (Z direction), and
wherein the at least one dummy terminal (90) includes a plurality of dummy terminals (90), which are provided to be spaced apart from one another in the second direction (Y direction).

### Supplementary Note 15

The semiconductor element of any one of Supplementary Notes 7 to 13, wherein the at least one dummy terminal (90) includes a plurality of dummy terminals (90), which are provided to surround the second electrode terminals (60) when viewed from a thickness direction (Z direction) of the semiconductor element (30).

### Supplementary Note 16

The semiconductor element of any one of Supplementary Notes 7 to 15, wherein a shape of the at least one dummy terminal (90) viewed from a thickness direction (Z direction) of the semiconductor element (30) is rectangular.

### Supplementary Note 17

The semiconductor element of Supplementary Note 9, wherein each of the first electrode terminals (50) includes a first seed layer (52) in contact with the first electrode (44A), and a first plating layer (53) laminated on the first seed layer (52),
wherein each of the second electrode terminals (60) includes a second seed layer (62) in contact with the second electrode (44B), and a second plating layer (63) laminated on the second seed layer (62), and
wherein the at least one dummy terminal (90) includes a third seed layer (92) in contact with the third electrode (44C), and a third plating layer (93) laminated on the third seed layer (92).

### Supplementary Note 18

A semiconductor device (10) including:
a substrate (100) having a substrate front surface (101) on which a plurality of first front surface wirings (111) and a plurality of second front surface wirings (112) are formed;
the semiconductor element (30) of any one of Supplementary Notes 1 to 17, which is mounted on both the plurality of first front surface wirings (111) and the plurality of second front surface wirings (112); and
a sealing resin (80) which seals the semiconductor element (30),
wherein the plurality of first electrode terminals (50) are individually connected electrically to the plurality of first front surface wirings (111), and
wherein the plurality of second electrode terminals (60) are individually connected electrically to the plurality of second front surface wirings (112).

### Supplementary Note 19

A semiconductor device (10) including:
a plurality of first leads (21) and a plurality of second leads (22);
the semiconductor element of any one of Supplementary Notes 1 to 17, which is mounted on both the plurality of first leads (21) and the plurality of second leads (22); and
a sealing resin (80) which seals the semiconductor element (30),
wherein the plurality of first electrode terminals (50) are individually connected electrically to the plurality of first leads (21), and
wherein the plurality of second electrode terminals (60) are individually connected electrically to the plurality of second leads (22).

### Supplementary Note 20

The semiconductor device of Supplementary Note 18, wherein the semiconductor element (30) includes a dummy terminal (90) formed in the second region (31B), and
wherein the dummy terminal (90) is insulated from the plurality of first front surface wirings (111) and the plurality of second front surface wirings (112).

### Supplementary Note 21

The semiconductor device of Supplementary Note 19, wherein the semiconductor element (30) includes a dummy terminal (90) formed in the second region (31B), and
wherein the dummy terminal (90) is insulated from the plurality of first leads (21) and the plurality of second leads (22).

### Supplementary Note 22

The semiconductor element of Supplementary Note 1, wherein a shape of each of the second electrode terminals (60) viewed from the thickness direction (Z direction) is different from a shape of each of the first electrode terminals (50) viewed from the thickness direction (Z direction).

### Supplementary Note 23

The semiconductor element of Supplementary Note 22, wherein the shape of each of the second electrode terminals (60) viewed from the thickness direction (Z direction) is rectangular.

### Supplementary Note 24

The semiconductor element of Supplementary Note 22 or 23, wherein the shape of each of the first electrode terminals (50) viewed from the thickness direction (Z direction) is circular.

### Supplementary Note 25

The semiconductor element of any one of Supplementary Notes 22 to 24, further including a dummy terminal (90) formed in the second region (31B),
wherein a shape of the dummy terminal (90) when viewed from the thickness direction

(Z direction) is rectangular.

### Supplementary Note 26

The semiconductor element of any one of Supplementary Notes 22 to 24, further including a dummy terminal (90) formed in the second region (31B),
wherein a shape of the dummy terminal (90) viewed from the thickness direction (Z direction) is circular.

### Supplementary Note 27

The semiconductor element of Supplementary Note 1, wherein a shape of each of the second electrode terminals (60) viewed from the thickness direction (Z direction) is the same as a shape of each of the first electrode terminals (50) viewed from the thickness direction (Z direction).

### Supplementary Note 28

The semiconductor element of Supplementary Note 27, wherein the shapes of each of the first electrode terminals (50) and each of the second electrode terminals (60) when viewed from the thickness direction (Z direction) are circular.

### Supplementary Note 29

The semiconductor element of Supplementary Note 27 or 28, further including a dummy terminal (90) formed in the second region (31B),
wherein a shape of the dummy terminal (90) viewed from the thickness direction (Z direction) is rectangular.

### Supplementary Note 30

The semiconductor element of Supplementary Note 27 or 28, further including a dummy terminal (90) formed in the second region (31B),
wherein a shape of the dummy terminal (90) viewed from the thickness direction (Z direction) is circular.

### Supplementary Note 31

The semiconductor element of Supplementary Note 7 or 8, wherein the at least one dummy terminal (90) is provided over the element front surface (31), and
wherein an area of the at least one dummy terminal (90) viewed from a thickness direction (Z direction) of the semiconductor element (30) is larger than an area of each of the first electrode terminals (50) viewed from the thickness direction (Z direction).

The above-described description is merely an example. Those skilled in the art may recognize that more conceivable combinations and substitutions are possible in addition to the constituent elements and methods (manufacturing processes) listed for the purposes of describing the techniques of the present disclosure. The present disclosure is intended to cover all alternatives, modifications, and changes that fall within the scope of the present disclosure, including the claims.

According to a semiconductor element and a semiconductor device in accordance with an embodiment of the present disclosure, it is possible to reduce variation in a connection state of electrode terminals.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A semiconductor element comprising:
an element front surface and an element back surface facing an opposite side from the element front surface;
a first electrode and a second electrode that are formed over the element front surface;
a plurality of first electrode terminals in contact with the first electrode;
a plurality of second electrode terminals in contact with the second electrode;
a first region in which the plurality of first electrode terminals are arranged; and
a second region in which the plurality of second electrode terminals are arranged,
wherein the number of the second electrode terminals per unit area in the second region is smaller than the number of the first electrode terminals per unit area in the first region, and
wherein an area of each of the second electrode terminals is larger than an area of each of the plurality of first electrode terminals when viewed from a thickness direction which is perpendicular to the element front surface.

2. The semiconductor element of claim 1, wherein the first region is a region in which a first transistor and a second transistor connected in series with each other are formed,
wherein the second region is a region in which a control circuit configured to control the first transistor and the second transistor is formed,
wherein the plurality of first electrode terminals are electrically connected to the first transistor and the second transistor, and
wherein the plurality of second electrode terminals are electrically connected to the control circuit.

3. The semiconductor element of claim 1, wherein a shape of each of the second electrode terminals viewed from the thickness direction is different from a shape of each of the first electrode terminals viewed from the thickness direction, and
wherein the shape of each of the first electrode terminals viewed from the thickness direction is circular.

4. The semiconductor element of claim 3, wherein the shape of each of the second electrode terminals viewed from the thickness direction is rectangular.

5. The semiconductor element of claim 1, wherein each of the first electrode terminals includes a first seed layer in contact with the first electrode, and a first plating layer laminated on the first seed layer, and
wherein each of the second electrode terminals includes a second seed layer in contact with the second electrode, and a second plating layer laminated on the second seed layer.

6. The semiconductor element of claim 5, wherein a thickness of the first seed layer and a thickness of the second seed layer are equal to each other.

7. A semiconductor element comprising:
an element front surface and an element back surface facing an opposite side from the element front surface;
a first electrode and a second electrode that are formed over the element front surface;
a plurality of first electrode terminals in contact with the first electrode;
a plurality of second electrode terminals in contact with the second electrode;
a first region in which the plurality of first electrode terminals are arranged; and
a second region in which the plurality of second electrode terminals are arranged,
wherein the number of the second electrode terminals per unit area in the second region is smaller than the number of the first electrode terminals per unit area in the first region, and
wherein at least one dummy terminal is provided in the second region.

8. The semiconductor element of claim 7, wherein the at least one dummy terminal is arranged to be closer to the second electrode terminals than the first electrode terminals.

9. The semiconductor element of claim 7, wherein the second electrode terminals are arranged to be spaced apart from the first electrode terminals in a first direction, when viewed from a thickness direction of the semiconductor element,
wherein the semiconductor element further comprises a third electrode formed in the second region of the element front surface,
wherein the third electrode is provided near the second electrode between the first electrode and the second electrode in the first direction, and
wherein the at least one dummy terminal is in contact with the third electrode.

10. The semiconductor element of claim 7, wherein a height dimension of the at least one dummy terminal is smaller than a height dimension of each of the second electrode terminals.

11. The semiconductor element of claim 7, wherein a height dimension of the at least one dummy terminal is smaller than a height dimension of each of the first electrode terminals.

12. The semiconductor element of claim 7, wherein an insulating layer having a first opening and a second opening is formed in the element front surface,
wherein the first electrode terminals are electrically connected to the first electrode at the first opening,
wherein the second electrode terminals are electrically connected to the second electrode at the second opening,
wherein the at least one dummy terminal is provided over the insulating layer, and
wherein an area of the at least one dummy terminal viewed from a thickness direction of the semiconductor element is larger than an area of each of the first electrode terminals viewed from the thickness direction.

13. The semiconductor element of claim 12, wherein a height dimension of the at least one dummy terminal is equal to a height dimension of each of the second electrode terminals.

14. The semiconductor element of claim 7, wherein the second electrode terminals are arranged to be spaced apart from the first electrode terminals in a first direction, when viewed from a thickness direction of the semiconductor element,
wherein the plurality of second electrode terminals are arranged to be spaced apart from one another in a second direction perpendicular to the first direction, when viewed from the thickness direction, and
wherein the at least one dummy terminal includes a plurality of dummy terminals, which are provided to be spaced apart from one another in the second direction.

15. The semiconductor element of claim 7, wherein the at least one dummy terminal includes a plurality of dummy terminals, which are provided to surround the second electrode terminals when viewed from a thickness direction of the semiconductor element.

16. The semiconductor element of claim 7, wherein a shape of the at least one dummy terminal viewed from a thickness direction of the semiconductor element is rectangular.

17. The semiconductor element of claim 9, wherein each of the first electrode terminals includes a first seed layer in contact with the first electrode, and a first plating layer laminated on the first seed layer,
wherein each of the second electrode terminals includes a second seed layer in contact with the second electrode, and a second plating layer laminated on the second seed layer, and
wherein the at least one dummy terminal includes a third seed layer in contact with the third electrode, and a third plating layer laminated on the third seed layer.

18. A semiconductor device comprising:
a substrate having a substrate front surface on which a plurality of first front surface wirings and a plurality of second front surface wirings are formed;
the semiconductor element of claim 1, which is mounted on both the plurality of first front surface wirings and the plurality of second front surface wirings; and
a sealing resin which seals the semiconductor element,
wherein the plurality of first electrode terminals are individually connected electrically to the plurality of first front surface wirings, and
wherein the plurality of second electrode terminals are individually connected electrically to the plurality of second front surface wirings.

19. A semiconductor device comprising:
a plurality of first leads and a plurality of second leads;
the semiconductor element of claim 1, which is mounted on both the plurality of first leads and the plurality of second leads; and
a sealing resin which seals the semiconductor element,
wherein the plurality of first electrode terminals are individually connected electrically to the plurality of first leads, and
wherein the plurality of second electrode terminals are individually connected electrically to the plurality of second leads.
